(19) United States
(12) Patent Application Publication
(10) Pub. No.: US 2020/0091459 A1
(43) Pub. Date: Mar. 19, 2020

(54) DISPLAY DEVICE AND METHOD FOR PRODUCING SAME

(71) Applicant: Sharp Kabushiki Kaisha, Sakai City, Osaka (JP)

(72) Inventors: Tohru SENOO, Sakai City (JP); Takeshi HIRASE, Sakai City (JP); Hisao OCHI, Sakai City (JP); Takashi OCHI, Sakai City (JP); Tohru SONODA, Sakai City (JP); Jumpei TAKAHASHI, Sakai City (JP); Akihiro MATSUI, Sakai City (JP); Yoshinobu MIYAMOTO, Sakai City (JP)

(21) Appl. No.: 16/494,358

(22) PCT Filed: Mar. 27, 2017
(86) PCT No.: PCT/JP2017/012372

§ 371 Date: Sep. 16, 2019

(51) Int. Cl. H01L 51/52; H01L 27/32; H01L 51/56

(52) U.S. Cl. CPC H01L 51/5253; H01L 2251/566; H01L 51/56; H01L 27/3258

(57) ABSTRACT

The organic EL display device includes a third organic insulating film pattern portion, which includes a groove on an upper surface thereof, between a display region and at least part of an edge portion of a TFT substrate. A first inorganic layer and a second inorganic layer of a sealing film cover the third organic insulating film pattern portion and at least part of the edge portion in a plan view, and are split apart in the groove.

### TECHNICAL FIELD

The disclosure relates to a display device and to a method for manufacturing the display device.

### BACKGROUND ART

EL display devices that use the Electro Luminescence (hereinafter referred to as “EL”) of a luminescent material is gathering attention as a display device offering a faster response speed in comparison to liquid crystal display devices, and also having a wider viewing angle.

This type of display device has a configuration in which light emitting elements, such as OLED elements, connected to thin film transistors (TFTs) are provided on a TFT substrate having a configuration in which the TFTs are provided on a support body such as a glass substrate or the like.

However, in general, this type of light emitting element is susceptible to the influence of moisture, oxygen, and the like, and the characteristics thereof deteriorate due to a reaction to small amounts of moisture, oxygen, or the like, thus impairing the life of the display device.

Thus, to prevent moisture or oxygen from penetrating into the light emitting element, the light emitting element is sealed with a sealing film including an inorganic layer. The inorganic layer has a moisture-proof function to prevent the penetration of moisture and functions as a barrier layer.

In commercial production, after a plurality of display devices are formed on a large mother substrate, individual display devices are obtained from the plurality of display devices by dividing the substrate along boundaries between the display devices adjacent to each other.

However, in a case that the substrate is divided in this way, and the inorganic layer of the sealing film is present on a division line, a crack generated by cutting the inorganic layer at the time of dividing the mother substrate may spread through the inorganic layer due to impact, vibrations, or the like, and may spread to a display region of the divided display device, when or after dividing the mother substrate.

In a case that the crack generated by dividing the mother substrate reaches into the display region of the display device in this manner, moisture or oxygen penetrates into the light emitting element, and the light emitting element is damaged, for example, thus reducing the reliability of the display device. Therefore, in the related art, to prevent the crack generated by dividing of the mother substrate, regions to be divided and regions on which the inorganic layer is formed need to be separated (see PTLs 1 and 2, for example).

### CITATION LIST

### Patent Literature

PTL 1: JP 2010-141181 A (published on Jun. 24, 2010)

PTL 2: JP 2014-127436 A (published on Jul. 7, 2014)

### SUMMARY

### Technical Problem

However, in a case that each sealing film is formed independently so that adjacent sealing films are not in contact with each other, and the inorganic layer is formed using a CVD mask, there is a problem in that a shadow is generated on an edge portion of the inorganic layer and the film thickness becomes thinner. Therefore, the edge portion of the inorganic layer needs to be sufficiently separated from the display region by a distance including machining accuracy and alignment accuracy of the CVD mask such that the shadow does not reach the display region. As a result, there is a problem in that frame narrowing becomes difficult, for example.

In light of the foregoing, an object of the disclosure is to provide a highly reliable display device in which a sealing film is formed on an edge portion of the display device and which can prevent a crack generated in the sealing film as a result of division of a mother substrate from spreading into a display region, and a method for manufacturing the display device.

### Solution to Problem

In order to solve the above-described problem, a display device according to an aspect of the disclosure is a display device including a support body, a plurality of light emitting elements provided in a display region on the support body, and a sealing film configured to seal the plurality of light emitting elements. The display device includes a resin layer including a groove on an upper surface thereof, the resin layer being provided between the display region and at least part of an edge portion of the support body in a plan view, and being separated from the at least part of the edge portion. The sealing film includes at least an inorganic layer. In a plan view, the inorganic layer covers the resin layer and the at least part of the edge portion, and is split apart in the groove.

In order to solve the above-described problem, a method for manufacturing a display device according to an aspect of the disclosure is a method for manufacturing a display device including a support body, a plurality of light emitting elements provided in a display region on the support body, and a sealing film configured to seal the plurality of light emitting elements. The method includes forming a resin layer including a groove in an upper surface thereof on a mother substrate configuring at least part of the support body, the resin layer being formed, in a plan view, between at least part of a scheduled division line, of a plurality of the scheduled division lines for dividing and singulating the mother substrate into the individual display devices, and the display region in a region surrounded by the plurality of scheduled division lines, the resin layer being separated from the at least part of the plurality of scheduled division lines, forming the sealing film, and dividing the mother substrate, on which the sealing film is formed, along the plurality of scheduled division lines surrounding around each of the display regions. The forming the sealing film includes forming an inorganic layer. In the forming the inorganic layer, the inorganic layer covers the resin layer, and, by forming the inorganic layer to also cover the at least part of the plurality of scheduled division lines, the inorganic layer is split apart in the groove.

### Advantageous Effects of Disclosure

According to an aspect of the disclosure, a highly reliable display device in which a sealing film is formed on an edge portion of the display device and which can prevent a crack generated in the sealing film as a result of division of a mother substrate from spreading into a display region, and a method for manufacturing the display device can be provided.

### BRIEF DESCRIPTION OF DRAWINGS

FIG. 1 is a cross-sectional view illustrating an example of a schematic configuration of an organic EL display device according to a first embodiment of the disclosure.

FIG. 2 is a plan view illustrating a schematic configuration of main portions of an organic EL substrate of an organic EL display device according to the first embodiment of the disclosure before performing singulation.

FIG. 3A is a cross-sectional view illustrating a schematic configuration of a third organic insulating film pattern portion in which a groove is formed according to the first embodiment of the disclosure, and FIG. 3B is a cross-sectional view illustrating a schematic configuration of the third organic insulating film pattern portion, when a first inorganic layer and a second inorganic layer are formed on the third organic insulating film pattern portion illustrated in FIG. 3A.

FIGS. 4A to 4C are cross-sectional views illustrating manufacturing steps of main portions of the organic EL display device according to the first embodiment of the disclosure in order of the steps.

FIG. 5A is a cross-sectional view illustrating a schematic configuration of the vicinity of a division line during singulation of the organic EL substrate according to the first embodiment of the disclosure, FIG. 5B is a cross-sectional view illustrating a schematic configuration of the vicinity of the division line during the singulation of the organic EL substrate, when the first inorganic layer and the second inorganic layer of a sealing film are formed on the division line on the organic EL substrate on which the third organic insulating film pattern portion including the groove is not formed, and FIG. 5C is a cross-sectional view illustrating a schematic configuration of the vicinity of the division line during the singulation of the organic EL substrate, when the sealing film is formed, using a CVD mask, being separated from the division line.

FIGS. 6A to 6C are each a cross-sectional view illustrating an example of a shape of the groove according to a first modified example of the first embodiment of the disclosure.

FIG. 7 is a cross-sectional view illustrating an example of a schematic configuration of the organic EL display device according to a second modified example of the first embodiment of the disclosure.

FIG. 8A is a plan view illustrating an example of a schematic configuration of the organic EL display device according to a third modified example of the first embodiment of the disclosure, FIG. 8B is a cross-sectional view taken along a line C-C illustrated in FIG. 8A, and FIG. 8C is a cross-sectional view taken along a line D-D illustrated in FIG. 8A.

FIG. 9 is a plan view illustrating an example of a schematic configuration of the organic EL display device according to a fourth modified example of the first embodiment of the disclosure.

### DESCRIPTION OF EMBODIMENTS

A detailed description follows regarding embodiments of the disclosure.

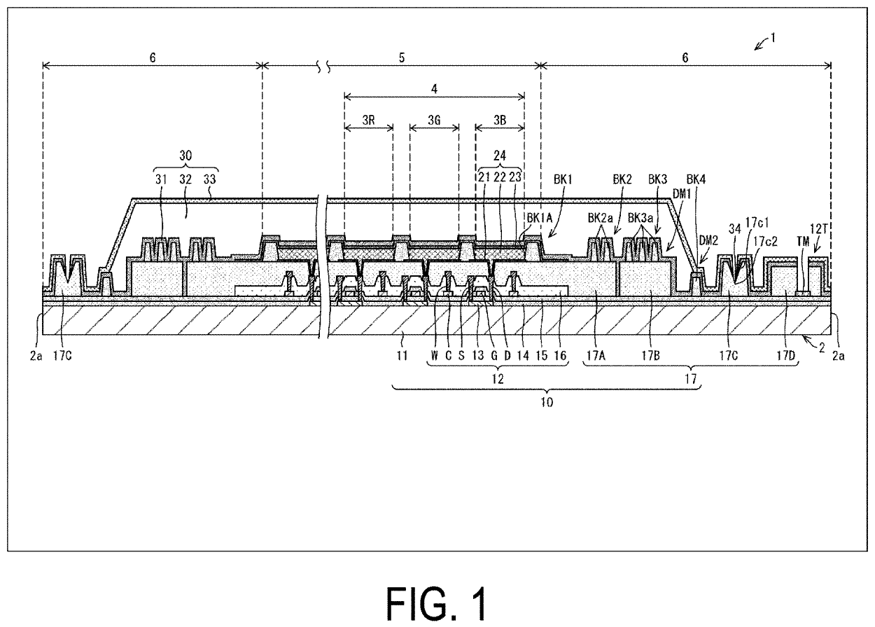

A description follows regarding an embodiment of the disclosure with reference to FIG. 1 to FIG. 9.

Note that, in the following description, as an example of a display device according to the present embodiment, an example is given of an organic EL display device provided with an Organic Light Emitting Diode (OLED) layer including OLED elements, known as organic EL elements, as light emitting elements.

### Schematic Configuration of Organic EL Display Device

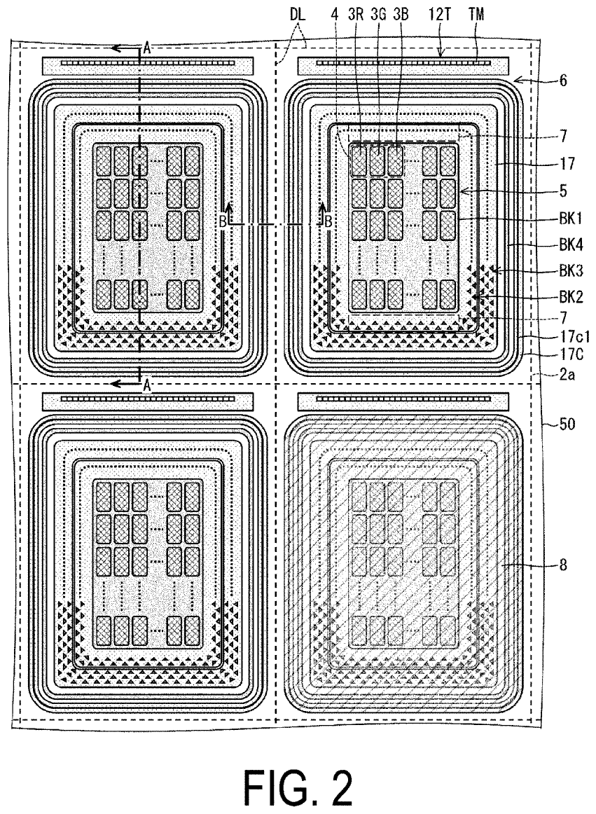

FIG. 1 is a cross sectional view illustrating an example of a schematic configuration of an organic EL display device 1 according to the present embodiment. FIG. 2 is a plan view illustrating a schematic configuration of main portions of an organic EL substrate 2 of the organic EL display device 1 according to the present embodiment, before performing singulation. Note that FIG. 1 illustrates a cross section of the organic EL display device 1 after the singulation, and the cross section corresponds to a cross section of the organic EL display device 1 illustrated in FIG. 2 taken along a line A-A in the direction of the arrows.

Note that in FIG. 2, for ease of illustration, apart from banks BK1 to BK4, a third organic insulating film pattern portion 17C, and a terminal portion 12T on which are provided a plurality of terminals TM that are terminals of each of wiring lines, illustration of other portions is omitted. Furthermore, in FIG. 2, for ease of illustration, a ratio of a frame region 6 with respect to a display region 5 is illustrated as being larger than in actuality.

As illustrated in FIG. 1, the organic EL display device 1 is provided with the organic EL substrate 2 and a drive circuit (not illustrated).

The organic EL substrate 2 has a configuration in which an OLED layer 20 configuring an OLED element (an organic EL element), a sealing film 30, and a cover body (not illustrated) are provided on a Thin Film Transistor (TFT) substrate 10, in that order from the TFT substrate 10 side.

Note that the organic EL display device 1 may be a flexible display device that has flexibility and can be bent, or may be a non-bendable display device that has rigidity.

### TFT Substrate 10

The TFT substrate 10 is provided with an electrically insulating support body 11 and a TFT layer 12 provided on the support body 11.

### Support Body 11

Examples of the support body 11 include a glass substrate, a plastic substrate, or a plastic film. Note that the support body 11 may be a flexible layered film in which a barrier layer (a moisture-proof layer) is provided on a plastic film (a resin layer). Furthermore, the layered film may have a configuration in which, on a face opposite to the face of the plastic film on which the barrier layer is provided, a lower face film that faces the outside is provided, with an adhesive layer interposed therebetween.

Examples of the resin used in the plastic film include a polyimide, polyethylene, a polyamide, or the like.

The barrier layer is a layer for preventing moisture or impurities from reaching the TFT layer 12 and the OLED layer 20 formed on the support body 11, and can be formed, for example, by a silicon oxide (SiOx) film, a silicon nitride (SiNx) film, or a layered film of these, formed by CVD.

The barrier layer is provided over the whole surface of the plastic film, such that the surface of the plastic film is not exposed. In this way, even when a material with poor liquid chemical resistance, such as a polyimide, is used as the plastic film, elution of the plastic film by liquid chemicals and process contamination can be prevented.

In a case that the organic EL display device 1 is the flexible display device, the lower face film is bonded to the lower face of the plastic film (the resin layer), from which the glass substrate has been peeled, in order to manufacture the organic EL display device 1 having excellent flexibility. A plastic film formed from a flexible resin is used as the lower face film. Examples of the flexible resin include polyethylene terephthalate, polyethylene naphthalate, a cycloolefin polymer, a polyimide, a polycarbonate, polyethylene, and an aramid.

### TFT Layer 12

The TFT layer 12 includes a semiconductor layer 13 formed in a plurality of island shapes, a gate insulating film 14 formed on the support body 11 covering the semiconductor layer 13, a plurality of gate electrodes G and a plurality of gate wiring lines (not illustrated) formed on the gate insulating film 14, an inorganic insulating film 15 (a first passivation film) covering the above-described gate electrodes G and wiring lines formed on the gate insulating film 14, a plurality of capacitance electrodes C formed on the inorganic insulating film 15, an inorganic insulating film 16 (a second passivation film) formed on the inorganic insulating film 15 covering the capacitance electrodes C, a plurality of source electrodes S, a plurality of drain electrodes D, and a plurality of wiring lines W, a plurality of source wiring lines (not illustrated), and a plurality of power source lines (not illustrated) formed on the inorganic insulating film 16, an organic insulating film 17 covering the above-described electrodes and wiring lines formed on the inorganic insulating film 16, and the terminal portion 12T on which the plurality of terminals TM (terminal electrodes) for connecting to the outside are provided.

The semiconductor layer 13 is formed of amorphous silicon, low-temperature polysilicon (LTPS), or an oxide semiconductor, for example. The gate insulating film 14 is formed of silicon oxide (SiOx) or silicon nitride (SiNx), or is configured by a layered film formed of these materials, for example.

The gate electrode G, the source electrode S, the drain electrode D, the capacitance electrode C, the wiring line W, a lead-out wiring line (not illustrated), and the terminal TM are formed of a single layer film or a layered film formed of a metal such as aluminum (Al), tungsten (W), molybdenum (Mo), tantalum (Ta), chromium (Cr), titanium (Ti), or copper (Cu), for example.

The inorganic insulating films 15 and 16 are formed of silicon oxide (SiOx) or silicon nitride (SiNx), for example. The organic insulating film 17 is formed of a photosensitive resin material such as a polyimide resin and an acrylic resin, for example.

The semiconductor layer 13, the gate electrode G, the inorganic insulating films 15 and 16, the source electrode S, and the drain electrode D configure the TFT 18.

The source electrode S and the drain electrode D are connected to the semiconductor layer 13 with a contact hole provided in the gate insulating film 14 and the inorganic insulating films 15 and 16 interposed therebetween. The source electrode S is connected to the power source line (not illustrated), for example. The drain electrode D is connected to a first electrode 21 with a contact hole extending through the organic insulating film 17 interposed therebetween. The wiring line W is connected to the capacitance electrode C with a contact hole provided in the inorganic insulating film 16 interposed therebetween.

Furthermore, the gate wiring line is connected to the gate electrode G, and the source wiring line is connected to the source electrode S. The gate wiring line and the source wiring line are intersected orthogonal to each other in a plan view.

Regions surrounded in a lattice pattern by the gate wiring line and the source wiring line are subpixels 3, and a single pixel 4 is formed by a set of the subpixels 3 of each of colors. In examples illustrated in FIG. 1 and FIG. 2, a red subpixel 3R, a green subpixel 3G, and a blue subpixel 3B are provided as the subpixels 3, and the single pixel 4 is formed by the red subpixel 3R, the green subpixel 3G, and the blue subpixel 3B. The TFT 18 is provided for each of the subpixels 3.

Note that, in FIG. 1, a case is illustrated, as an example, in which the TFT 18 has a top gate structure with the semiconductor layer 13 as a channel, but the TFT 18 may have a bottom gate structure.

As illustrated in FIG. 1 and FIG. 2, the organic EL display device 1 includes the display region 5 in which the subpixels 3 are arranged in a matrix pattern and on which an image is displayed and the frame region 6 which is a peripheral region surrounding the periphery of the display region 5 and on which the subpixels 3 are not arranged.

As illustrated in FIG. 1, the terminal TM is provided in the frame region 6. The terminal TM is electrically connected to the gate wiring line, for example, with the lead-out wiring line (not illustrated) interposed therebetween. The source wiring line is connected to the terminal TM (not illustrated) with the lead-out wiring line (not illustrated) interposed therebetween.

The terminal portion 12T, in which the terminals TM are provided, is provided between the display region 5 in which the organic EL elements 24 is provided and part of an edge portion 2a of the TFT substrate 10. In the example illustrated in FIG. 1 and FIG. 2, the terminal portion 12T faces one side of the TFT substrate 10 and is provided between a sealing region 8 that is surrounded by the bank BK4 (to be described later) and seals the organic EL elements 24 and an organic layer 32 (to be described later) of the sealing film 30 sealing the organic EL elements 24, and the edge portion 2a of the one side of the TFT substrate 10. However, the present embodiment is not limited to this example, and the terminal portion 12T may be provided facing two sides of the TFT substrate 10. Note that the sealing region 8 is provided in a region indicated by diagonal lines in FIG. 2, and for convenience of illustration, the sealing region 8 is illustrated in FIG. 2 only in a section corresponding to the sealing region 8 of one organic EL display device 1. However, it goes without saying that the sealing region 8 is also provided for the other organic EL display devices 1.

As illustrated in FIG. 1, the organic insulating film 17 flattens steps on the TFTs 18 and the wiring lines W in the display region 5, and also covers edge portions of the terminals TM.

A portion of the terminal TM that is not covered by the organic insulating film 17 is electrically connected to a flexible film cable, a flexible printed circuit (FPC) substrate, an external circuit such as an integrated circuit (IC) with an anisotropic conductive film (ACF) or the like interposed therebetween.

Furthermore, as illustrated in FIG. 1, the organic insulating film 17 covers an end face of the inorganic insulating film 16.

The organic insulating film 17 is divided into a plurality of patterns that are separated from each other. The organic insulating film 17 is provided in the display region 5 as a flattening film, and is also provided in the frame region 6. The organic insulating film 17 according to the present embodiment includes a first organic insulating film pattern portion 17A, a second organic insulating film pattern portion 17B, the third organic insulating film pattern portion 17C, and a fourth organic insulating film pattern portion 17D. The second organic insulating film pattern portion 17B to the fourth organic insulating film pattern portion 17D are formed of the same material as the first organic insulating film pattern portion 17A, and are provided in the same layer as the first organic insulating film pattern portion 17A, while being separated from the first organic insulating film pattern portion 17A. Note that the first organic insulating film pattern portion 17A to the fourth organic insulating film pattern portion 17D will be described below.

### OLED Layer 20

The OLED layer 20 includes the first electrode 21 (a lower electrode) formed on the organic insulating film 17, the banks BK (wall bodies, embankments), an organic EL layer 22 formed on the first electrode 21 and formed from an organic layer including at least a light emitting layer, and a second electrode 23 (an upper electrode) formed on the organic EL layer 22.

The first electrode 21, the organic EL layer 22, and the second electrode 23 configure the organic EL element 24 (the OLED element). Note that, in the present embodiment, the layers between the first electrode 21 and the second electrode 23 are collectively referred to as the organic EL layer 22.

Furthermore, an optical adjustment layer (not illustrated) that performs optical adjustment, and a protection layer that protects the second electrode 23 such that oxygen or moisture does not penetrate into the organic EL element 24 from outside may be formed on the second electrode 23. In the present embodiment, the organic EL layer 22 formed on each of the subpixels 3, the pair of electrode layers (the first electrode 21 and the second electrode 23) that sandwich the organic EL layer 22, and the optical adjustment layer and the protection layer (not illustrated) that are formed as necessary, are referred to together as the organic EL element 24.

The first electrode 21 is formed on the organic insulating film 17 in the display region 5. The first electrode 21 allows holes to be injected (supplied) into the organic EL layer 22, and the second electrode 23 allows electrons to be injected into the organic EL layer 22. The holes and the electrons injected into the organic EL layer 22 are recombined in the organic EL layer 22, and thus form excitons. The formed excitons emit light as they become deactivated from an excited state to a ground state, and the emitted light is emitted to the outside from the organic EL element 24.

The first electrode 21 is electrically connected to the TFT 18 with a contact hole formed in the organic insulating film 17 interposed therebetween.

The first electrode 21 is a pattern electrode formed in an island-shaped pattern for each of the subpixels 3. Meanwhile, the second electrode 23 is a solid-like common electrode provided in common to each of the subpixels 3.

As illustrated in FIG. 2, second electrode connecting portions 7 in which second electrode connecting electrodes (not illustrated) each connected to the second electrode 23 are provided are provided along and outside one pair of sides facing each other of two pair of sides of the display region 5.

The bank BK includes the bank BK1 (a lattice-shaped bank) disposed in the display region 5 and the banks BK2 to BK4 (frame-shaped banks) disposed in the frame region 6. Note that each of the banks BK1 to BK4 will be described below together with the first organic insulating film pattern portion 17A to the fourth organic insulating film pattern portion 17D.

A peripheral portion of the first electrode 21 is covered by the bank BK1. As illustrated in FIG. 1 and FIG. 2, in the bank BK1, an opening BK1A is provided for each of the subpixels 3. Exposed portions of the first electrode 21 exposed by the opening BK1A form a light emitting region of each of the subpixels 3.

In a case that, for the organic EL layer 22 of the organic EL element 24, separate patterning is performed such that a different color light is emitted for each of the subpixels 3, as illustrated in FIG. 1, the organic EL layer 22 is formed for each of the regions (the subpixel 3) surrounded by the bank BK1. Thus, the organic EL display device 1 illustrated in FIG. 1 emits red color light from the red subpixel 3R, emits green color light from the green subpixel 3G, and emits blue color light from the blue subpixel 3B. In this way, in a case that the organic EL display device 1 is provided with the organic EL element 24 formed using the RGB separate patterning method, full color image display can be performed using the red color light, the green color light, and the blue color light, without using a color filter.

For example, the organic EL layer 22 is configured by layering a hole injecting layer, a hole transport layer, a light emitting layer, an electron transport layer, and an electron injecting layer, in this order from the first electrode 21 side. Note that a single layer may have a plurality of functions. For example, in place of the hole injection layer and the hole transport layer, a hole injection-cum-transport layer having the functions of both these layers may be provided. In addition, in place of the electron injection layer and the electron transport layer, an electron injection-cum-transport layer having the functions of both these layers may be provided. In addition, a carrier blocking layer may be provided between the layers as appropriate.

Note that the above-described layering order is for a case in which the first electrode 21 is an anode electrode and the second electrode 23 is a cathode electrode, and when the first electrode 21 is the cathode electrode and the second electrode 23 is the anode electrode, the order of each of the layers configuring the organic EL layer 22 is inverted.

In a case that the organic EL display device 1 is a bottom-emitting type configured to emit light from the back surface side of the support body 11, it is preferable that the second electrode 23 be formed by a reflective electrode material, and the first electrode 21 be formed by a transparent or semi-transparent light-transmissive electrode material.

A transparent conductive film such as indium tin oxide (ITO) and indium zinc oxide (IZO), or a thin film of a metal such as gold (Au), platinum (Pt), and nickel (Ni) can be used as the first electrode 21, for example. To inject electrons into the light emitting layer, a metal with a small work function, such as lithium (Li), cerium (Ce), barium (Ba), and aluminum (Al), or an alloy containing these metals, such as a magnesium alloy (MgAg or the like) and an aluminum alloy (AlLi, AlCa, AlMg, or the like), is used as the second electrode 23.

Meanwhile, in a case that the organic EL display device 1 is a top-emitting type configured to emit light from the sealing film 30 side, it is preferable that the first electrode 21 be formed by a reflective electrode material, and the second electrode 23 be formed by a transparent or semi-transparent light-transmissive electrode material.

The first electrode 21 and the second electrode 23 may each have a single layer structure or may each have a layered structure. For example, in a case that the organic EL element 24 is a top-emitting organic EL element, the first electrode 21 may have a layered structure configured by a reflective electrode and a transparent electrode.

### Organic Insulating Film 17 and Banks BK

In the present embodiment, by forming the organic insulating film 17 on the TFT substrate 10 up to the outer side of the sealing region 8 surrounded by the bank BK4, as a resin layer provided with a crack stopper, the third organic insulating film pattern portion 17C, in which a groove 17c1 is formed, is formed surrounding the sealing region 8.

As described above, the organic insulating film 17 is divided into the first organic insulating film pattern portion 17A to the fourth organic insulating film pattern portion 17D.

As illustrated in FIG. 1, the first organic insulating film pattern portion 17A is formed continuously from the display region 5 to the frame region 6. The second organic insulating film pattern portion 17B to the fourth organic insulating film pattern portion 17D are formed in the frame region 6. Of the second organic insulating film pattern portion 17B to the fourth organic insulating film pattern portion 17D, the second organic insulating film pattern portion 17B is formed in a frame shape being separated from the first organic insulating film pattern portion 17A to surround the first organic insulating film pattern portion 17A. The third organic insulating film pattern portion 17C is formed in a frame shape being separated from the second organic insulating film pattern portion 17B to surround the second organic insulating film pattern portion 17B. The fourth organic insulating film pattern portion 17D covers the edge portions of the terminals TM.

The first organic insulating film pattern portion 17A is a flattening film, and as described above, flattens the steps on the TFTs 18 and the wiring lines W in the display region 5. Note that the TFTs 18 and the organic EL elements 24 are provided on the first organic insulating film pattern portion 17A, but the TFTs 18 and the organic EL elements 24 are not provided on the second organic insulating film pattern portion 17B, the third organic insulating film pattern portion 17C, and the fourth organic insulating film pattern portion 17D.

As described above, on the first organic insulating film pattern portion 17A formed continuously from the display region 5 to the frame region 6, the bank BK1 is formed in the display region 5, while the bank BK2 is formed in the frame region 6.

The bank BK1 functions as an edge cover that inhibits, at the peripheral portion of the first electrode 21, a short circuit with the second electrode 23 due to electrode concentration or thinning of the organic EL layer 22, and also functions as a subpixel isolation layer that isolates the subpixels 3 from each other such that electric current does not leak to the adjacent subpixel 3.

The bank BK1 is provided in a lattice pattern in a plan view, for example, covering each edge of the first electrodes 21 arranged in a matrix pattern in the display region 5. The bank BK2 is formed in a frame shape surrounding the display region 5.

The bank BK2 is formed by a plurality of dot-shaped banks BK2a that are separated from each other, and each of the dot-shaped banks is arranged in a plurality of rows to form an intermittent frame shape. As illustrated in FIG. 2, the bank BK2 has a configuration in which the dot-shaped banks BK2a of the adjacent rows are disposed regularly in a zig-zag shape with respect to each other in a plan view.

The second organic insulating film pattern portion 17B is formed in a frame shape outside the first organic insulating film pattern portion 17A (in other words, in a plan view, between the first organic insulating film pattern portion 17A and the edge portion 2a of the organic EL substrate 2) to surround the first organic insulating film pattern portion 17A. The bank BK3 is formed in a frame shape on the second organic insulating film pattern portion 17B to surround the bank BK2.

The bank BK3 is formed by a plurality of dot-shaped banks BK3a that are separated from each other, and each of the dot-shaped banks is arranged in a plurality of rows to form an intermittent frame shape. As illustrated in FIG. 2, the bank BK3 has a configuration in which the dot-shaped banks BK3a of the adjacent rows are disposed regularly in a zig-zag shape with respect to each other in a plan view.

The second organic insulating film pattern portion 17B is separated from the first organic insulating film pattern portion 17A, and thus the second organic insulating film pattern portion 17B on which the bank BK3 is provided is used as a first dam portion DM1 configured to stop the penetration of moisture into the TFTs 18 and the organic EL elements 24 inside the first organic insulating film pattern portion 17A.

The bank BK4, which is formed in a frame shape formed by a continuous line rather than in a dot-shape, is formed outside the first dam portion DM1 (in other words, between the first dam portion DM1 and the edge portion 2a of the organic EL substrate 2) to surround the first dam portion DM1. The bank BK4 is formed on the inorganic insulating film 15 in the frame region 6. The bank BK4 functions as an organic layer stopper that holds back an organic insulating material forming the organic layer 32 in the sealing film 30, which will be described below.

Further, since the first organic insulating film pattern portion 17A and the second organic insulating film pattern portion 17B are separated from each other, the bank BK4 is used as a second dam portion DM2 configured to prevent the penetration of moisture into the TFTs 18 and the organic EL elements 24 inside the first organic insulating film pattern portion 17A.

Note that, to improve coverage of a formation surface on which each of the banks BK is formed, a cross-section thereof is preferably a forwardly tapered shape.

The third organic insulating film pattern portion 17C is formed in a frame shape outside the bank BK4 (in other words, between the bank BK4 and the edge portion 2a of the organic EL substrate 2) to surround the bank BK4.

The groove 17c1, which is formed in a fine continuous line-shape, is formed in a frame shape, in a plan view, on the upper surface of the third organic insulating film pattern portion 17C to surround the bank BK4. Note that the groove 17c1 will be described in detail below.

As described above, the fourth organic insulating film pattern portion 17D covers the edge portions of the terminals TM.

In the present embodiment, as illustrated in FIG. 2, the display region 5 is formed in a quadrilateral shape. Thus, the outer shape of the first organic insulating film pattern portion 17A is formed, corresponding to the quadrilateral-shaped display region 5, in a quadrilateral shape having a substantially similar shape to the outer shape of the display region 5. Furthermore, the outer shapes (the outer edge shapes of the frames) of the second organic insulating film pattern portion 17B, the third organic insulating film pattern portion 17C, and the bank BK4 surrounding the first organic insulating film pattern portion 17A are also formed in a quadrilateral shape having a substantially similar shape to the outer shape of the display region 5.

Note that four corner portions of each of the first organic insulating film pattern portion 17A, the second organic insulating film pattern portion 17B, the third organic insulating film pattern portion 17C, and the bank BK4 may be curved lines as illustrated in FIG. 2, or may be right angles.

The first organic insulating film pattern portion 17A is formed such that a straight line distance from each edge portion of the display region 5 to each inner side face of the first organic insulating film pattern portion 17A facing each edge portion is constant. Furthermore, the second organic insulating film pattern portion 17B is formed such that a straight line distance from each outer side face of the first organic insulating film pattern portion 17A to each inner side face of the second organic insulating film pattern portion 17B facing each outer side face is constant. The bank BK4 is formed such that a straight line distance from each outer side face of the second organic insulating film pattern portion 17B to each inner side face of the bank BK4 facing each outer side face is constant. The third organic insulating film pattern portion 17C is formed such that a straight line distance from each outer side face of the bank BK4 to each inner side face of the third organic insulating film pattern portion 17C facing each of the outer side faces is constant.

As described above, outside the display region 5 on which the lattice-shaped bank BK1 is provided, the frame-shaped bank BK2, the frame-shaped bank BK3, the first dam portion DM1 formed by the second organic insulating film pattern portion 17B, the second dam portion DM2 formed by the frame-shaped bank BK4, and the third organic insulating film pattern portion 17C provided with the groove 17c1 are provided in this order from the inside to the outside with the lattice-shaped bank BK1 at the center.

The banks BK1 to BK4 are formed from an organic insulating material. The banks BK1 to BK4 are formed, for example, from a photosensitive resin, such as an acrylic resin, or a polyimide resin. The banks BK1 to BK4 can be formed in the same step, for example.

When forming the organic layer 32 of the sealing film 30, which will be described below, the banks BK2 to BK4 define edges of the organic layer 32 by reducing the flow rate of a liquid organic insulating material (ink), which is a material of the organic layer 32, in stages, thereby regulating wet-spreading of the organic insulating material.

In particular, after the liquid organic insulating material that forms the organic layer 32 is applied using the ink-jet method or the like, the dot-shaped banks BK2a and BK3a align edges of the wetly spreading liquid organic insulating material, block the flow of the wetly spreading organic insulating material, and align edge portions of the organic insulating material to be in a substantially straight line shape.

Furthermore, since the organic insulating material wetly spreads while passing through the banks BK2 and BK3, the banks BK2 and BK3 function as resistance. As a result of passing through the banks BK2 and BK3, the speed of the wet-spreading of the organic insulating material decreases. According to the present embodiment, by providing the banks BK2 and BK3 closer to the display region 5 than the bank BK4 in this way, the flow of the organic insulating material can be blocked, and an overflow of the organic insulating material beyond the bank BK4 to the outside (particularly, reaching onto the terminal portion 12T) can be prevented.

The organic insulating material forming the organic layer 32 is held back by the bank BK4, while covering an edge portion of the bank BK4 on the bank BK3 side. As a result, the organic layer 32 comes in contact with the edge portions of the bank BK4 closer to the bank BK3, with a first inorganic layer 31 interposed therebetween.

Furthermore, although not illustrated, in the present embodiment, the second electrode 23 is formed covering the bank BK2 formed along a side of the first organic insulating film pattern portion 17A on which the second electrode connecting portion 7 is provided.

Thus, since the bank BK2 is formed by the plurality of dot-shaped banks BK2a, the second electrode 23 is formed covering the steps of the dot-shaped banks BK2a, and at the same time, is formed on planar portions located in gaps between the dot-shaped banks BK2a. Since the bank BK2 is formed by the plurality of dot-shaped banks BK2a in this way, the second electrode 23 and the second electrode connecting portion 7 can be reliably made conductive.

### Sealing Film 30

The sealing film 30 includes the first inorganic layer 31 (a lower layer inorganic sealing layer), the organic layer 32 (a first organic sealing layer), and a second inorganic layer 33 (an upper layer inorganic sealing layer), layered in this order from the TFT substrate 10 side.

The first inorganic layer 31 and the second inorganic layer 33 have a moisture-proof function to prevent the penetration of moisture, and function as barrier layers to inhibit deterioration of the organic EL element 24 caused by moisture or oxygen.

The organic layer 32 is used as a buffer layer (a stress relief layer), which relieves stress in the first inorganic layer 31 and the second inorganic layer 33 in which film stress is large, performs flattening and burying of pinholes by burying step portions and foreign material on the surface of the OLED layer 20 in the display region 5, and further, prevents the occurrence of cracks in the second inorganic layer 33 when the second inorganic layer 33 is layered, by flattening a foundation of the second inorganic layer 33.

The first inorganic layer 31 and the second inorganic layer 33 are each formed by CVD, for example, and each can be formed by a silicon oxide film, a silicon nitride film, or a silicon oxynitride film, or by a layered film of these films. Each of the thickness of the first inorganic layer 31 and the thickness of the second inorganic layer 33 is 500 to 1500 nm, for example.

The organic layer 32 is a light-transmissive organic insulating film that is thicker than the first inorganic layer 31 and the second inorganic layer 33, and may be formed of a photosensitive resin such as an acrylic resin, an epoxy resin, and a silicone resin. The organic layer 32 can be formed, for example, by performing ink-jet application of an ink including this type of photosensitive resin, as the organic insulating material, onto the first inorganic layer 31, and then performing ultraviolet (UV) curing. The thickness of the organic layer 32 is 4 to 12 μm, for example.

The first inorganic layer 31 is formed on the support body 11 over the whole surface of the display region 5 and the frame region 6, apart from a surface on the terminals TM, the first inorganic layer 31 covering, in a plan view, the second electrode 23, the organic insulating film 17 apart from a part of the terminal portion 12T (in the present embodiment, the first organic insulating film pattern portion 17A to the third organic insulating film pattern portion 17C, and an edge portion of the fourth portion organic insulating film pattern portion 17D on the third organic insulating film pattern portion 17C side), the organic EL elements 24, the inorganic insulating film 15, and the banks BK that are not covered by the second electrode 23 (in the present embodiment, a part of the bank BK2, and the banks BK3 and BK4).

However, the first inorganic layer 31 is split apart (pattern cut) in the groove 17c1 provided in the third organic insulating film pattern portion 17C.

In addition to covering the first organic insulating film pattern portion 17A and the second organic insulating film pattern portion 17B, the organic EL elements 24, and the banks BK1 to BK3, the organic layer 32 preferably covers the edge portion of the bank BK4 on the bank BK3 side and a part of an upper portion of the bank BK4 with the first inorganic layer 31 interposed therebetween, the bank BK4 functioning as the organic layer stopper. The organic layer 32 is provided in the sealing region 8 (see FIG. 2) that is surrounded by the bank BK4 serving as the organic layer stopper and is configured to seal the organic EL elements 24.

The second inorganic layer 33 is formed superimposing on the first inorganic layer 31. In a case that a cross section of the organic layer 32 is exposed, moisture or the like penetrates from this cross section. Thus, to prevent the cross section of the organic layer 32 from being exposed, the second inorganic layer 33 covers the first inorganic layer 31 so as to seal the organic layer 32 between the first inorganic layer 31 and the second inorganic layer 33.

The second inorganic layer 33 is formed on the first inorganic layer 31 over the whole surface of the display region 5 and the frame region 6, apart from the surface on the terminals TM, the second inorganic layer 33 covering, in a plan view, the second electrode 23, the organic insulating film 17 apart from the part of the terminal portion 12T (in the present embodiment, the first organic insulating film pattern portion 17A to the third organic insulating film pattern portion 17C, and the edge portion of the fourth organic insulating film pattern portion 17D on the third organic insulating film pattern portion 17C side), the organic EL elements 24, the inorganic insulating film 15, and the banks BK that are not covered by the second electrode 23 (the part of the bank BK2, and the banks BK3 and BK4), with at least the first inorganic layer 31, of the first inorganic layer 31 and the organic layer 32, interposed therebetween.

However, similarly to the first inorganic layer 31, the second inorganic layer 33 is split apart (pattern cut) in the groove 17c1 provided in the third organic insulating film pattern portion 17C.

Note that, as described above, an inorganic layer or an organic layer (not illustrated), such as the optical adjustment layer or the electrode protection layer, may be formed between the second electrode 23 and the sealing film 30.

### Groove 17c1

Next, the groove 17c1 will be described below with reference to FIG. 1 to FIGS. 3A and 3B.

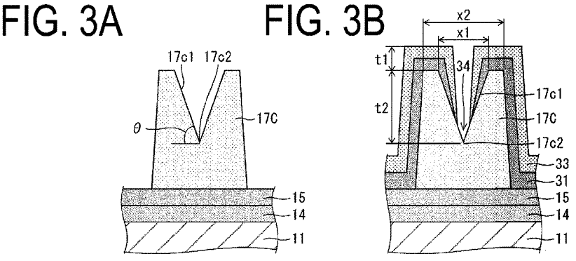

FIG. 3A is a cross-sectional view illustrating a schematic configuration of the third organic insulating film pattern portion 17C in which the groove 17c1 is formed, according to the present embodiment, and FIG. 3B is a cross-sectional view illustrating a schematic configuration of the third organic insulating film pattern portion 17C when the first inorganic layer 31 and the second inorganic layer 33 are formed on the third organic insulating film pattern portion 17C illustrated in FIG. 3A.

As described above, the groove 17c1 is formed in the upper surface of the third organic insulating film pattern portion 17C formed outside the sealing region 8 surrounded by the bank BK4, as illustrated in FIG. 1 to FIGS. 3A and 3B.

The groove 17c1 functions as a crack stopper that prevents cracks, which are generated in the sealing film 30 on the edge portion 2a of the organic EL substrate 2 as a result of the division of the mother substrate 50 (see FIG. 2), from spreading into the display region 5.

In the CVD used for forming an inorganic sealing film, a low temperature that is 80° C. or lower is generally used, for example, in order to prevent thermal damage to a function layer (specifically, an EL layer such as the organic EL layer 22) of the light emitting element, and the substrate temperature has a similar temperature. Thus, even with plasma CVD, film growth on the substrate is unlikely to occur, and there is little seeping of an inorganic sealing film material into the groove 17c1, in particular, seeping of an inorganic sealing film material into a shadow section.

Thus, as described above, when the groove 17c1 is formed in the upper surface of the third organic insulating film pattern portion 17C, and the first inorganic layer 31 and the second inorganic layer 33 are formed on the third organic insulating film pattern portion 17C, the first inorganic layer 31 and the second inorganic layer 33 cannot extend as far as the groove 17c1, and the first inorganic layer 31 and the second inorganic layer 33 are naturally split apart (pattern cut) at a bottom portion 17c2 of the groove 17c1 when forming the first inorganic layer 31 and the second inorganic layer 33.

When the first inorganic layer 31 and the second inorganic layer 33 are formed on the third organic insulating film pattern portion 17C in which, for example, a V-shaped groove is formed as the groove 17c1, the first inorganic layer 31 and the second inorganic layer 33 cannot extend as far as the groove 17c1, and, with the bottom portion 17c2 of the groove 17c1 acting as a base point, the first inorganic layer 31 and the second inorganic layer 33 are naturally split apart (pattern cut) when forming the first inorganic layer 31 and the second inorganic layer 33. As a result, a split portion 34 in which the first inorganic layer 31 and the second inorganic layer 33 are split apart is formed in the bottom portion 17c2 of the groove 17c1.

In the present embodiment, the width (groove width) and the depth of the groove 17c1 may be appropriately set to a width and a depth by which the first inorganic layer 31 and the second inorganic layer 33 layered on the third organic insulating film pattern portion 17C are split apart in the groove 17c1, in accordance with the shape, width, and depth of the groove 17c1, as well as the thickness and the like of the first inorganic layer 31 and the second inorganic layer 33, and the width and the depth of the groove 17c1 are not particularly limited.

However, as illustrated in FIG. 3B, when the width of the groove 17c1 (namely, the groove width or the width of the upper end of the groove 17c1) in a plan view is x1, the width, in the same direction as the width x1, at the outermost surface of the third organic insulating film pattern portion 17C (resin layer) including the groove 17c1 is x2, and the total layer thickness of the first inorganic layer 31 and the second inorganic layer 33 is t1, the width x1 preferably satisfies t1<x1<x2.

Note that here, the width (groove width) of the groove 17c1 in a plan view refers to the length in the short direction of the upper end of the groove 17c1, namely, the length in the short direction of the groove 17c1 on the same plane as the outermost surface of the third organic insulating film pattern portion 17C. In addition, the length in the short direction of the groove 17c1 refers to the length of the groove 17c1 in the direction orthogonal to the direction (in other words, in a direction traversing the edge portion 2a) in which the groove 17c1 extends (in other words, in the direction along the edge portion 2a of the organic EL substrate 2).

Furthermore, the first inorganic layer 31 and the second inorganic layer 33 having the same film thickness as the first inorganic layer 31 and the second inorganic layer 33 in the display region 5 are formed on the third organic insulating film pattern portion 17C (more specifically, on the top surface of the third organic insulating film pattern portion 17C).

As an example, the width x1 is preferably within a range of 2 μm to 5 μm, for example. By setting the width x1 to be the above-described width, the splitting of the first inorganic layer 31 and the second inorganic layer 33 easily occurs. Furthermore, the width x2 is preferably within a range of 7 μm to 25 μm, for example, from a perspective of pattern forming. As described above, both the thickness of the first inorganic layer 31 and the thickness of the second inorganic layer 33 are 500 to 1500 nm, for example, and the layer thickness t1 is 1 μm to 3 μm, for example.

Furthermore, when the depth of the groove 17c1 (the length in the normal direction) is t2, the depth t2 of the groove 17c1 is preferably within a range of 0.5 μm to 2 μm, for example. By setting the depth t2 to be the above-described depth, the splitting of the first inorganic layer 31 and the second inorganic layer 33 easily occurs.

The organic insulating film 17 is formed to have a thickness that allows the groove 17c1 to be formed. In the present embodiment, the third organic insulating film pattern portion 17C, which is the resin layer including the groove 17c1, is formed by the organic insulating film 17, and the first organic insulating film pattern portion 17A of the organic insulating film 17 is the flattening film that compensates for the steps caused by the TFTs 18. Thus, the organic insulating film 17 is formed to have a thickness that allows the steps caused by the TFTs 18 to be compensated for and the groove 17c1 to be formed. The thickness of the organic insulating film 17 is 1 to 3 μm, for example.

Furthermore, as illustrated in FIG. 3A, an angle formed by an inner wall of the groove 17c1 and a surface parallel to the surface of the TFT substrate 10 (in other words, an angle formed by the inner wall of the groove 17c1 and a horizontal surface: hereinafter, referred to as a “taper angle θ”) is preferably within a range of 70° to 120°, for example. By setting the taper angle θ to the above-described angle, the splitting of the first inorganic layer 31 and the second inorganic layer 33 easily occurs.

### Cover Body

As described above, a cover body (not illustrated) is provided on the sealing film 30. The cover body is a function layer having at least one of a protection function, an optical compensation function, and a touch sensor function, and, in a case that the organic EL display device 1 is the flexible display device, for example, the cover body may be a protection film that functions as a support body when the glass substrate is peeled off. Furthermore, in a case that the organic EL display device 1 is a non-bendable and rigid display device, the cover body may be a counter substrate such as the glass substrate, and a filling layer formed from a filling material (not illustrated) may further be provided between the counter substrate and the organic EL substrate 2.

In addition, the cover body may be provided with a function film, such as a polarizing film and a touch sensor film, or may be provided with a polarizer, a touch panel, and the like.

### Method for Manufacturing Organic EL Display Device 1

Next, a method for manufacturing the organic EL display device 1 will be described below with reference to FIG. 1 to FIGS. 4A to 4C.

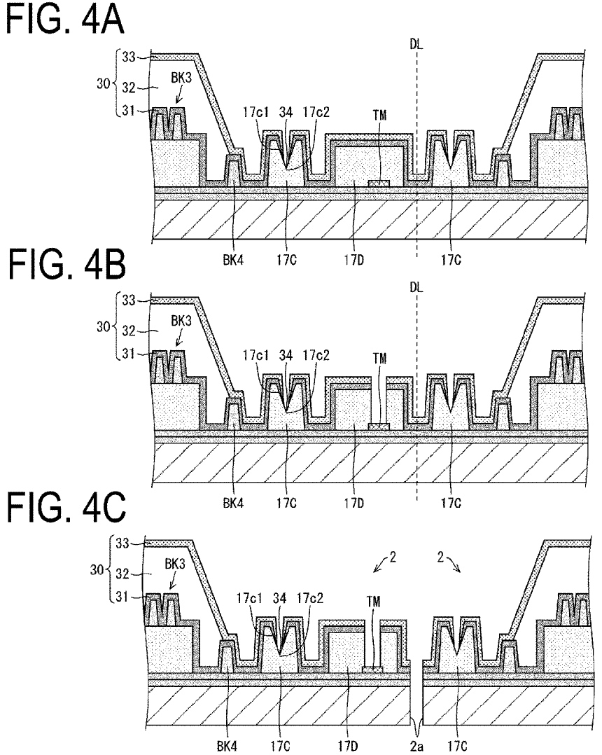

FIGS. 4A to 4C are cross-sectional views illustrating manufacturing steps of main portions of the organic EL display device 1 according to the present embodiment, in order of the steps. FIGS. 4A to 4C each illustrate a cross section of the organic EL display device 1 illustrated in FIG. 2 taken along a line B-B in the direction of arrows.

First, as illustrated in FIG. 1, on the mother substrate 50 (see FIG. 2) configuring the support body 11 and formed by a large glass substrate or the like, the semiconductor layer 13, the gate insulating film 14 formed on the mother substrate 50 covering the semiconductor layer 13, the plurality of gate electrodes G and the plurality of gate wiring lines (not illustrated) formed on the gate insulating film 14, the inorganic insulating film 15 covering the gate electrodes G and the gate wiring lines formed on the gate insulating film 14, the plurality of capacitance electrodes C formed on the inorganic insulating film 15, the inorganic insulating film 16 formed on the inorganic insulating film 15 covering the capacitance electrodes C, the plurality of source electrodes S, the plurality of drain electrodes D, the plurality of wiring lines W, the plurality of source wiring lines (not illustrated), and the plurality of power source lines (not illustrated) that are formed on the inorganic insulating film 16, and the terminal portion 12T including the plurality of terminals TM are formed by a known method.

Note that in a case that the organic EL display device 1 is a flexible display device, as the mother substrate 50, a substrate is used that is obtained by forming a resin layer (a plastic film), such as a polyimide layer, and a moisture-proof layer, which configure the support body 11, on a large carrier substrate such as a glass substrate.

Next, a photosensitive resin, such as an acrylic resin or a polyimide resin, is applied to the mother substrate 50 on which the above-described wiring lines and the like are formed, and patterning is performed by photolithography or the like, thus the organic insulating film 17 including the first organic insulating film pattern portion 17A to the fourth organic insulating film pattern portion 17D are formed.

Note that, at this time, the fourth organic insulating film pattern portion 17D is formed covering the terminals TM in the terminal portion 12T.

In addition, at this time, the groove 17c1 can be formed at the same time as the formation of the first organic insulating film pattern portion 17A to the fourth organic insulating film pattern portion 17D by using a halftone mask having partially different light transmittance, for example.

However, the present embodiment is not limited to this example, and, for example, after forming the first organic insulating film pattern portion 17A to the fourth organic insulating film pattern portion 17D, by performing the photolithography or the like once again, or by performing laser irradiation or the like on a position in which the groove 17c1 is formed in the third organic insulating film pattern portion 17C, the first organic insulating film pattern portion 17A to the fourth organic insulating film pattern portion 17D, and the groove 17c1 may be formed in separate steps.

As a result, as illustrated in FIG. 1, FIG. 2, and FIG. 3A, when the mother substrate 50 is divided along each of division lines DL, in a region, surrounded by the division lines DL, which forms the organic EL substrate 2 of each of the organic EL display devices 1, the groove 17c1 is formed along each of the division lines DL that forms the edge portion 2a of the organic EL substrate 2 on each side of the organic EL substrate 2 other than the side facing the terminal portion 12T, and the groove 17c1 is also formed between the display region 5 and the terminal portion 12T such that the groove 17c1 passes between the display region 5 and the terminal portion 12T and surrounds the display region 5.

Note that here, the division line DL refers to a scheduled division line along which the mother substrate 50 is divided and singulated into the organic EL substrates 2 corresponding to the individual organic EL display devices 1.

By the above-described step, the mother substrate 50, on which the TFT layer 12 is formed, is formed as the TFT substrate 10.

Next, the first electrode 21 is pattern formed in the matrix pattern by a sputtering method or the like. At this time, the first electrode 21 is electrically connected to the drain electrode D with the contact hole formed in the organic insulating film 17 interposed therebetween.

Next, an organic film (not illustrated) that is formed, for example, of a photosensitive resin such as an acrylic resin or a polyimide resin, is formed to cover the first electrode 21, the organic insulating film 17, and the inorganic insulating films 15 and 16. Then, as illustrated in FIGS. 1 and 2, the banks BK (BK1 to BK4) formed by the organic film are pattern formed by photolithography or the like. Note that each of the banks BK1 to BK4 can be pattern formed using the same material in the same step. However, the banks BK1 to BK4 may also be formed in separate steps using mutually different masks.

After that, as illustrated in FIG. 1, the organic EL layer 22 is formed by separately patterning vapor deposition, corresponding to each of the subpixels 3R, 3G, and 3B, such that light emitting layers of each color cover the region surrounded by the bank BK1 (namely, the opening BK1A). Note that in the film formation of the organic EL layer 22, a method other than the vapor deposition method may be used, such as a paint-on method, the ink-jet method, or a printing method.

To perform the full color display, as an example, the light emitting layers can be pattern formed by the separately patterning vapor deposition, that is, for each of the light emission colors, as described above. However, the present embodiment is not limited to this example, and, to perform the full color display, a configuration may be used in which the white color light emitting organic EL element 24 that uses a white color (W) light emitting layer configured to emit white light, is used in combination with a color filter (CF) layer (not illustrated), and the light emission color for each of the subpixels 3 is selected. Furthermore, while using the light emitting layer whose light emission color is the color W, the full color image display may be realized by introducing a microcavity structure for each of the subpixels 3. Note that, when changing the light emission color of each of the subpixels 3 using the method using the CF layer, the microcavity structure, or the like, it is not necessary for the light emitting layers to be separately patterned for each of the subpixels 3.

Next, the second electrode 23 is pattern formed by vapor deposition using a vapor deposition mask, for example, over the whole surface of the display region 5 on the TFT substrate 10 covering the organic EL layer 22 and the bank BK1, so as to be electrically connected to the second electrode connecting electrode of the second electrode connecting portion 7 and to expose regions other than these regions.

In this way, the organic EL element 24 formed by the first electrode 21, the organic EL layer 22, and the second electrode 23 can be formed on the TFT substrate 10.

Next, on the TFT substrate 10 on which the organic EL elements 24 are formed, the first inorganic layer 31 is formed in a maskless manner over the whole surface of the mother substrate 50 by a CVD method or the like, without using a CVD mask. As a result, the first inorganic layer 31 covering each of the division lines DL of the mother substrate 50 is formed, as illustrated in FIG. 3A.

Next, the liquid organic insulating material (the ink) including the photosensitive resin is applied over the whole surface of the display region 5 using the ink-jet method or the like.

Next, the liquid organic insulating material that is wetly spread inside the region surrounded by the bank BK4 is cured. As a result, the organic layer 32 whose edge portion along the bank BK4 has a uniform film thickness is formed.

After that, on the first inorganic layer 31, the second inorganic layer 33 is formed in a maskless manner in the same manner as the first inorganic layer 31, such that the organic layer 32 is sealed by the first inorganic layer 31 and the second inorganic layer 33.

As a result, the sealing film 30 formed by the first inorganic layer 31, the organic layer 32, and the second inorganic layer 33 is formed.

For example, as described above, plasma CVD is used for forming the first inorganic layer 31 and second inorganic layer 33. The organic layer 32 is held back by the bank BK4 to be contained inside the region surrounded by the bank BK4. Thus, the sealing film 30 on the third organic insulating film pattern portion 17C and around the third organic insulating film pattern portion 17C does not include the organic layer 32, and only the first inorganic layer 31 and the second inorganic layer 33 are layered therein.

According to the present embodiment, as described above, by forming the groove 17c1 on the upper surface of the third organic insulating film pattern portion 17C, when forming the first inorganic layer 31 and the second inorganic layer 33, the first inorganic layer 31 and the second inorganic layer 33 are naturally split apart (pattern cut) at the bottom portion 17c2 of the groove 17c1. As a result, the split portion 34 in which the first inorganic layer 31 and the second inorganic layer 33 are split apart is formed in the bottom portion 17c2 of the groove 17c1.

Note that the split portion 34 is a split naturally formed during the film formation of each of the films (specifically, during the film formation of the first inorganic layer 31, and during the film formation of the second inorganic layer 33). Therefore, unlike a case in which the inorganic sealing film is physically cut after the formation of the inorganic sealing film (after the film formation of the first inorganic layer 31 and the second inorganic layer 33, for example), when the first inorganic layer 31 is split apart and when the second inorganic layer 33 is split apart, a subsequent crack does not occur in the first inorganic layer 31 and the second inorganic layer 33.

Note that, as described above, the first inorganic layer 31 and the second inorganic layer 33 having the same film thickness as the first inorganic layer 31 and the second inorganic layer 33 in the display region 5 are formed on the third organic insulating film pattern portion 17C (more specifically, on the top surface of the third organic insulating film pattern portion 17C).

After that, as illustrated in FIG. 4B, by irradiating the terminal portion 12T with a laser, a terminal exposing step is performed to expose the terminals TM of the terminal portion 12T.

Next, after a protective film or the like (not illustrated) is bonded onto the sealing film 30, the mother substrate 50 on which the TFT layer 12, the OLED layer 20, and the sealing film 30 are formed is divided (diced) along the division lines DL such that each of the display regions 5 on the mother substrate 50 is surrounded by the division lines DL. As a result, the mother substrate 50, on which the TFT layer 12, the OLED layer 20, and the sealing film 30 are formed, is singulated into the individual organic EL substrates 2, as illustrated in FIG. 4C. Note that, for the dividing, a laser, a metal blade, or the like can be used.

In the obtained organic EL substrate 2, the first inorganic layer 31 and the second inorganic layer 33 cover the edge portion 2a (edge) of the organic EL substrate 2 in a plan view, and peripheral edge portions (namely, all edges) of the first inorganic layer 31 and the second inorganic layer 33 overlap with peripheral edge portions (namely, all edges (the edge portions 2a)) of the organic EL substrate 2.

Note that, in a case that the organic EL display device 1 is the flexible display device, after the protection film or the like is bonded onto the sealing film 30, using laser irradiation, the carrier substrate is then peeled by ablation at an interface between the carrier substrate and the resin layer (the plastic film) of the mother substrate 50. Then, after the lower face film is bonded to the peeling surface, the singulation of the organic EL substrate 2 is performed.

After that, as necessary, a function film, such as a polarizing film and a touch sensor film, or a polarizer, a touch panel or the like, is bonded to the organic EL substrate 2.

### Advantageous Effects

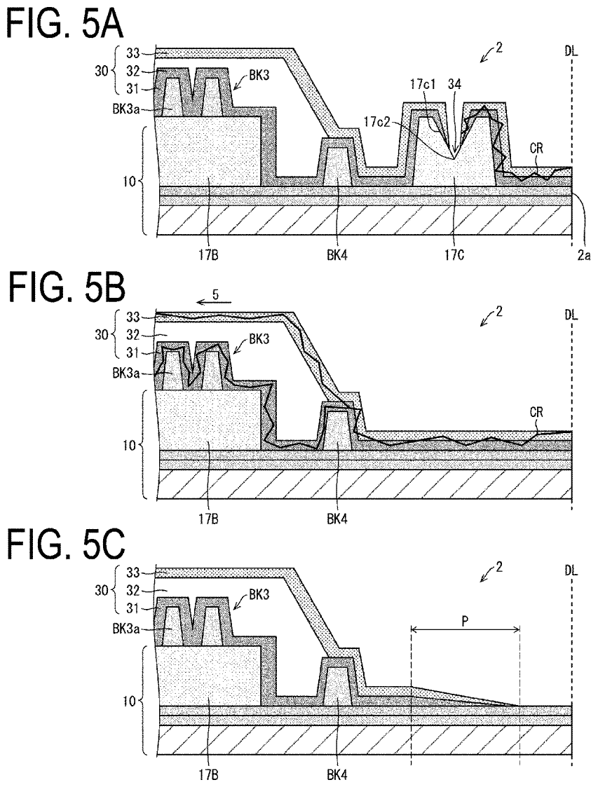

FIG. 5A is a cross-sectional view illustrating a schematic configuration of the vicinity of the division line DL during the singulation of the organic EL substrate 2 according to the present embodiment, FIG. 5B is a cross-sectional view illustrating a schematic configuration of the vicinity of the division line DL during the singulation of the organic EL substrate 2 when the first inorganic layer 31 and the second inorganic layer 33 of the sealing film 30 are formed on the division line DL of the organic EL substrate 2 on which the third organic insulating film pattern portion 17C including the groove 17c1 is not formed, and FIG. 5C is a cross-sectional view illustrating a schematic configuration of the vicinity of the division line DL during the singulation of the organic EL substrate 2 when the sealing film 30 is formed using the CVD mask to be separated from the division line DL.

As illustrated in FIGS. 5A and 5B, in a case that the inorganic sealing film such as the first inorganic layer 31 and the second inorganic layer 33 is present on the division line DL, a crack CR may be generated in the inorganic sealing film on the division line DL as a result of the inorganic sealing film being cut.

At this time, as illustrated in FIG. 5B, if a resin layer provided with a crack stopper, such as the third organic insulating film pattern portion 17C including the groove 17c1, is not formed, a crack generated in the inorganic sealing film may spread through the inorganic sealing film, and may spread into the display region 5 of the divided organic EL substrate 2.

However, according to the present embodiment, as described above, since the third organic insulating film pattern portion 17C including the groove 17c1 is provided outside the display region 5 (outside the sealing region 8, for example) to surround the display region 5, when forming the inorganic sealing film, the inorganic sealing film is naturally split apart at the bottom portion 17c2 of the groove 17c1.

Thus, according to the present embodiment, as illustrated in FIG. 5A, as a result of the first inorganic layer 31 and the second inorganic layer 33 being split apart, the split portion 34 is provided at the bottom portion 17c2 of the groove 17c1.

Thus, according to the present embodiment, as illustrated in FIG. 5A, even when the crack CR is generated in the sealing film 30 on the division line DL as a result of the sealing film 30 being cut, spreading of the crack CR is stopped by the split portion 34. Thus, according to the present embodiment, the crack CR generated in the inorganic sealing film does not spread into the display region 5, and moisture or oxygen does not penetrate into the display region 5. Thus, the highly reliable organic EL display device 1 can be formed.

Note that when the sealing film 30 in each of the organic EL substrates 2 is formed independently using a CVD mask such that the sealing films 30 of the adjacent organic EL substrates 2 on the mother substrate 50 do not contact each other, the inorganic sealing film is not present on the division line DL, as illustrated in FIG. 5C, so the crack CR generated in the inorganic sealing film does not spread into the display region 5.

However, when the inorganic sealing layer is formed using the CVD mask, a shadow is generated on an edge portion of the inorganic sealing layer, as illustrated in FIG. 5C.

At this time, a region on which the shadow is generated (a shadow region P) is approximately from 300 to 400 μm. Since the film thickness of the inorganic sealing film decreases in the shadow region P, barrier properties are reduced therein. For this reason, the edge portion of the inorganic layer needs to be sufficiently separated from the display region 5 such that the shadow region P is not present in the display region 5, while also taking into account the machining accuracy and alignment accuracy of the CVD mask. Thus, when the division line DL and the formation region of the sealing film 30 are separated using the CVD mask, frame narrowing becomes impossible.

In contrast, according to the present embodiment, the shadow region P can be eliminated, so there is no such limitation. According to the present embodiment, since the inorganic sealing film can be provided on the division line DL, a margin for the forming accuracy of the inorganic sealing film can be secured. According to the present embodiment, since there is no need to separately dispose the edge portion of the inorganic sealing film and the divided region, the frame narrowing can be performed.

Note that in FIGS. 5A to 5C, although the position of the division line DL is aligned, the frame narrowing can be easily performed as long as the groove 17c1 (more specifically, the third organic insulating film pattern portion 17C provided with the groove 17c1) is disposed in a position close to the display region 5. The groove 17c1 can be formed very slightly inside the division line DL (in other words, very slightly inside the edge portion 2a of the organic EL substrate 2).

Furthermore, although not illustrated, in a case that a groove is formed on the division line DL by removing the inorganic sealing film on the division line DL after forming the sealing film 30, photolithography using a photoresist, etching, and peeling steps are required after forming the sealing film 30, and these steps need to be performed in a low temperature process so as not to damage the organic EL element 24. Therefore, in a case that the groove is formed on the division line DL as described above, not only is an extra burden added in terms of equipment costs and running costs, but also yield decreases due to the increased number of steps.

In contrast, according to the present embodiment, since only the photolithography step for forming the eaves body 41 is required to be added, the burden of adding the number of steps is relatively low. In addition, by forming the eaves body 41 before the film forming step of the sealing film 30, particularly before the film forming step of the organic EL 22, material loss in a case that a pattern failure of the eaves body 41 occurs can be significantly reduced.

### First Modified Example

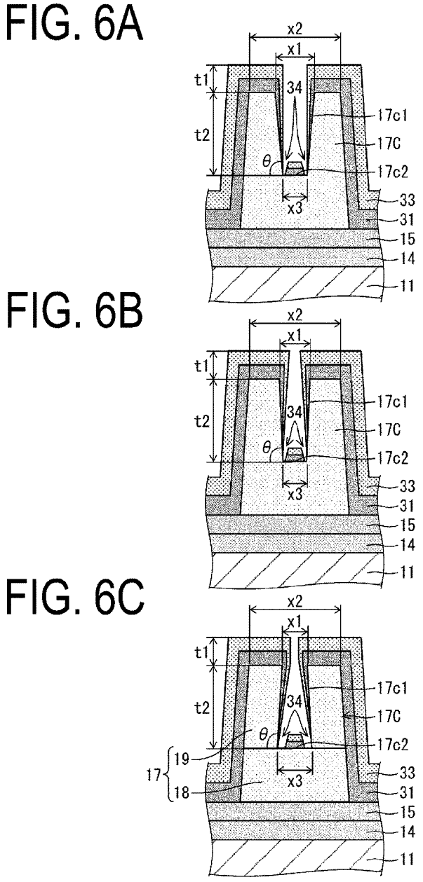

FIGS. 6A to 6C are each a cross-sectional view illustrating an example of the shape of the groove 17c1 according to the present modified example.

In FIG. 1 and FIGS. 3A and 3B to FIG. 5A, a case is illustrated, as an example, in which the groove 17c1 is a V-shaped groove having a V-shape in a cross-sectional view.

However, the present embodiment is not limited to this example. As illustrated in FIG. 6A, the groove 17c1 may be a reversely tapered recessed groove having the taper angle θ of less than 90° and, for example, having reversely tapered inner wall surfaces in a cross-sectional view.

In this case, since the bottom portion 17c2 (lower end) of the groove 17c1 includes a flat portion, the first inorganic layer 31 and the second inorganic layer 33 are layered on (attached to) inner walls of the groove 17c1 and the flat portion of the bottom portion 17c2. However, since the first inorganic layer 31 and the second inorganic layer 33 do not extend as far as edge portions of the bottom portion 17c2, the first inorganic layer 31 and the second inorganic layer 33 are split apart in the edge portions, and the split portions 34 are formed in the edge portions.

In addition, although a case is illustrated, as an example, in which the taper angle θ is less than 90° in FIG. 1, FIG. 6A, and the like, as described above, the taper angle θ may be set to be 90° or more.

Thus, as illustrated in FIG. 6B, the groove 17c1 may have the taper angle θ of 90° and may be a recessed groove having perpendicular inner wall surfaces.

Furthermore, as illustrated in FIG. 6C, the groove 17c1 may be a forwardly tapered recessed groove having the taper angle θ greater than 90° and, for example, having forwardly tapered inner wall surfaces in a cross-sectional view.

In the above description, although a case is described, as an example, in which the groove 17c1 is formed by photolithography using a positive-working photosensitive resin for the organic insulating film 17, the present embodiment is not limited to this example, and the groove 17c1 may be formed by laser machining, cutting, or the like, for example.

For example, the groove 17c1 illustrated in FIG. 6C can be formed by irradiating the third organic insulating film pattern portion 17C with a laser light after forming the third organic insulating film pattern portion 17C in which the groove 17c1 is not formed.

Furthermore, as illustrated in FIG. 6C, the organic insulating film 17 may be formed by a plurality of resin layers. In this case, the whole organic insulating film 17 may be formed by the plurality of resin layers, and for example, only the third organic insulating film pattern portion 17C, or a portion of the organic insulating film pattern portion including the third organic insulating film pattern portion 17C may be formed by the plurality of resin layers.

In FIG. 6C, a case is illustrated, as an example, in which the third organic insulating film pattern portion 17C has a layered structure in which a second resin layer 19 is layered on a first resin layer 18. However, the present embodiment is not limited to this example.

Note that, when the third organic insulating film pattern portion 17C has the layered structure in which the plurality of resin layers are layered, each of the resin layers may be formed of resins having different light transmittance and absorption rates, or may be formed using a combination of a positive-working photosensitive resin and a negative-working photosensitive resin.

In this way, the groove 17c1 can be machined into a desired shape by a known method, for example, by selecting a material, selecting a machining method, adjusting energy output conditions such as the amount of light exposure or the laser output, or the like.

When the bottom 17c2 of the groove 17c1 includes the flat portion as described above, as illustrated in FIGS. 6A to 6C, when the width (groove width) of the flat portion of the bottom portion 17c2 of the groove 17c1 is x3, and the total layer thickness of the first inorganic layer 31 and the second inorganic layer 33 is t1, the width x3 preferably satisfies 0<x3<t1.

Note that here, the width (groove width) of the flat portion of the bottom portion 17c2 of the groove 17c1 refers to the length in the short direction of the flat portion of the bottom portion 17c2 of the groove 17c1 (similarly to the width x1, the direction orthogonal to the direction in which the groove 17c1 extends).

Furthermore, in this case as well, as described above, when the width of the upper end of the groove 17c1 is x1, the width, in the same direction as the width x1, at the outermost surface of the third organic insulating film pattern portion 17C including the groove 17c1 is x2, and the total layer thickness of the first inorganic layer 31 and the second inorganic layer 33 is t1, the width x1 preferably satisfies t1<x1<x2.

The width x3 is not particularly limited as long as 0<x3<t1 is satisfied, but the width x3 is preferably within a range of 0.5 μm to 2 μm, for example. The widths x1 and x2, the layer thickness t1, and the depth t2 are set as described above.

### Second Modified Example

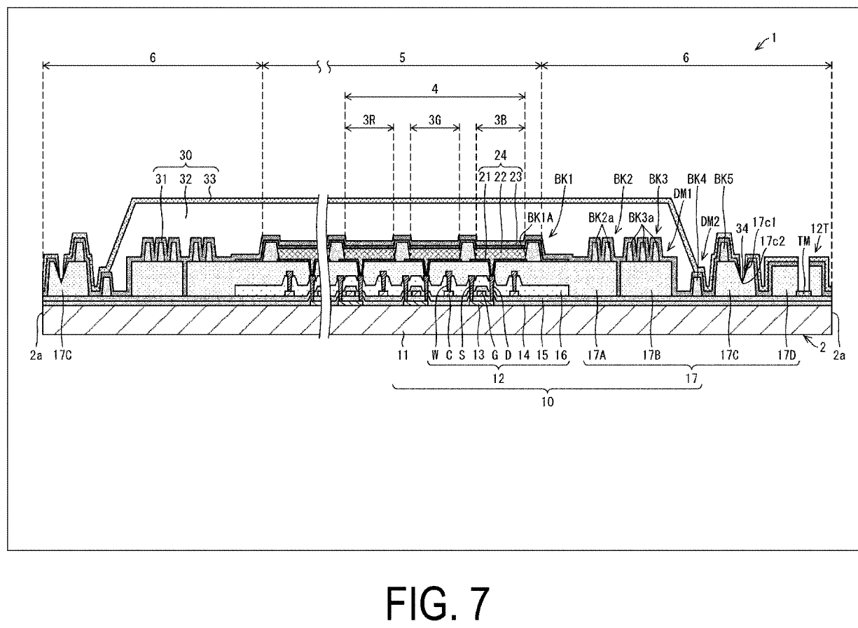

FIG. 7 is a cross-sectional view illustrating an example of a schematic configuration of the organic EL display device 1 according to the present modified example.

The organic EL display device 1 according to the present modified example differs from the organic EL display device 1 illustrated in FIG. 1 to FIG. 5A in that the third organic insulating film pattern portion 17C is provided with a frame-shaped bank BK5 formed by a continuous line to surround the bank BK4, and the groove 17c1 is provided in the third organic insulating film pattern portion 17C outside the bank BK5 to surround the bank BK5.

In the present modified example, the frame-shaped bank BK2, the frame-shaped bank BK3, the frame-shaped bank BK4, and the frame-shaped bank BK5 are formed outside the lattice-shaped bank BK1 as the banks BK, and are provided in this order from the inside to the outside with the lattice-shaped bank BK1 at the center.

The bank BK5 can be formed of the same material as the banks BK1 to BK4, for example, using an acrylic resin, a polyimide resin, or the like, and the banks BK1 to BK5 can be formed in the same step, for example.

The bank BK5 holds back the organic insulating material, which forms the organic layer 32, when the bank BK4 fails to hold back the organic layer 32. Also, since the third organic insulating film pattern portion 17C is separated from the first organic insulating film pattern portion 17A, the bank BK4, and the second organic insulating film pattern portion 17B, the bank BK5 is used as a third dam portion configured to prevent the penetration of moisture into the TFTs 18 and the organic EL elements 24 inside the first organic insulating film pattern portion 17A.

In the present modified example, by extending the third organic insulating film pattern portion 17C, which is used as the third dam portion, toward the edge portion 2a closer to the organic EL substrate 2, in other words, closer to the division line DL, and by forming the groove 17c1 in the third organic insulating film pattern portion 17C in this way, the third organic insulating film pattern portion 17C can deploy a plurality of functions, namely, it can be used both as the third dam portion and as a body forming the crack stopper.

Note that, although not illustrated, organic insulating film pattern portions may be formed for the third dam portion and the groove 17c1, respectively. For example, an organic insulating film pattern portion (not illustrated), which is provided with the bank BK5 and surrounds the bank BK4, may be further formed as the third dam portion between the third organic insulating film pattern portion 17C in which the groove 17c1 is formed, and the bank BK4, and a configuration may be adopted in which the third organic insulating film pattern portion 17C in which the groove 17c1 is formed is formed surrounding the third dam portion.

In addition, in FIG. 1 and FIG. 4B, a case is illustrated, as an example, in which, by exposing the terminals by irradiating the terminal portion 12T with the laser, an opening, which has the same shape as and exposes the terminal TM, is formed in the fourth organic insulating film pattern portion 17D and the first inorganic layer 31 and the second inorganic layer 33 covering the fourth organic insulating film pattern portion 17D.

However, the present embodiment is not limited to this example. Regardless of the presence of the bank BK5, the shape (the size in a plan view) of the opening that is formed in the fourth organic insulating film pattern portion 17D and exposes the terminal, and the shape (the size in a plan view) of the opening that is formed in the first inorganic layer 31 and the second inorganic layer 33 covering the fourth organic insulating film pattern portion 17D may be the same as each other, as illustrated in FIG. 1 and FIG. 4B, or may be different from each other, as illustrated in FIG. 7.

Note that the difference in the shape of the opening may occur, for example, due to a difference in the absorption rate of the laser used for exposing the terminal. Furthermore, by changing the laser intensity for the first inorganic layer 31 and the second inorganic layer 33 from the laser intensity for the fourth organic insulating film pattern portion 17D, the shape of the opening formed in each of the first inorganic layer 31. the second inorganic layer 33, and the fourth organic insulating film pattern portion 17D may be changed.

Furthermore, as described above, since the third organic insulating film pattern portion 17C in which the groove 17c1 is formed is provided, the organic EL display device 1 can form the first inorganic layer 31 and the second inorganic layer 33 in a maskless manner. However, the fourth organic insulating film pattern portion 17D in which the opening is provided in advance to expose the terminal TM may be formed, and the first inorganic layer 31 and the second inorganic layer 33 may be formed using a CVD mask. The CVD mask includes a plurality of mask openings, and is formed such that lines passing over each of the terminals TM of the adjacent plurality of terminal portions 12T on either side of the division line DL are covered, and such that, of four sides of the region surrounded by the division lines DL, at least the division line DL on the side on which the terminal portion 12T is not provided is positioned inside the mask opening, and such that a region surrounding the division line DL on the side on which the terminal portion 12T is not provided is open. In this case as well, since the third organic insulating film pattern portion 17C in which the groove 17c1 is formed is provided, the first inorganic layer 31 and the second inorganic layer 33 can be split apart, and the spreading of cracks into the display region 5 can be prevented. Furthermore, the frame narrowing of the side on which the terminal portion 12T is not provided can be achieved.

### Third Modified Example

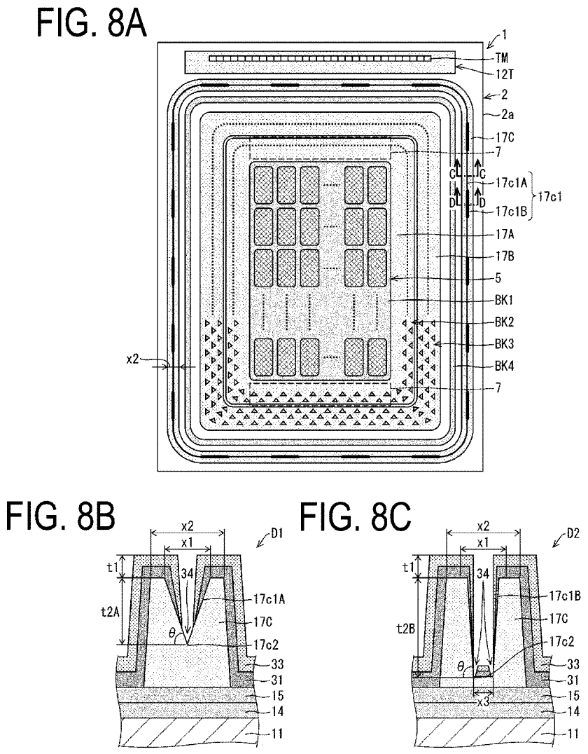

FIG. 8A is a plan view illustrating an example of a schematic configuration of the organic EL display device 1 according to the present modified example, FIG. 8B is a cross-sectional view taken along a line C-C illustrated in FIG. 8A, and FIG. 8C is a cross-sectional view taken along a line D-D illustrated in FIG. 8A.

In the organic EL display device 1 according to the present modified example, as illustrated in FIGS. 8A to 8C, a groove 17c1A and a groove 17c1B, which is deeper than the groove 17c1A, may be provided in the third organic insulating film pattern portion 17C as the groove 17c1. The grooves 17c1A and 17c1B may be periodically formed, for example, and a shallow groove portion D1 provided with the relatively shallow groove 17c1A and a deep groove portion D2 provided with the relatively deep groove 17c1B may be alternately provided at a uniform period in the third organic insulating film pattern portion 17C.

Furthermore, in the organic EL display device 1 according to the present modified example, the shape of the groove 17c1 may be partially different. As illustrated in FIGS. 8A to 8C, the organic EL display device 1 according to the present modified example may have a configuration in which the grooves 17c1A and 17c1B have different shapes from each other and the grooves 17c1A and 17c1B having the different shapes are periodically formed, for example. For example, the shallow groove portion D1 and the deep groove portion D2 may be respectively provided with the grooves 17c1A and 17c1B having the different shapes.

Note that in FIGS. 8A to 8C, a case is illustrated, as an example, in which a V-shaped groove is provided in the shallow groove portion D1 as the groove 17c1A, and a recessed groove is provided in the deep groove portion D2 as the groove 17c1B, but the present modified example is not limited to this example. For example, the recessed groove may be provided in the shallow groove portion D1 as the groove portion 17c1A, and the V-shaped groove may be provided in the deep groove portion D2 as the groove 17c1B.

Furthermore, the groove 17c1A and the groove 17c1B may have different taper angles due to differences in the groove shapes, for example, and may have different taper angles due to differences in the depths. For example, a relatively shallow V-shaped groove may be provided in the shallow groove portion D1 as the groove 17c1A, a relatively deep V-shaped groove may be provided in the deep groove portion D2 as the groove 17c1B, and the groove 17c1A and the groove 17c1B may have the different taper angles θ due to differences in the depths thereof.

Note that in FIGS. 8A to 8C, a case is illustrated, as an example, in which the shallow groove portions D1 are provided in corner portions of the organic EL substrate 2, but the deep groove portions D2 may be provided in the corner portions of the organic EL substrate 2. For example, in FIG. 8A, the shallow groove portions D1 and the deep groove portions D2 may be reversed in position.

Furthermore, in FIGS. 8A to 8C, a case is illustrated, as an example, in which the third organic insulating film pattern portion 17C provided with the grooves 17c1A and 17c1B is formed in a single frame shape, but the present modified example is not limited to this example. For example, the third organic insulating film pattern portion 17C provided with the shallow groove portions D1 and the deep groove portions D2 may be formed in a multiple frame shape, such as a double frame shape, a triple frame shape, or the like, and the shallow groove portions D1 and the deep groove portions D2 may be disposed to respectively form zig-zag patterns in adjacent frames.

Note that the taper angle θ of the groove 17c1 (the grooves 17c lA and 17c1B) is preferably within the range of 70° to 120°, for example, as described above.

Furthermore, regardless of whether the groove 17c1 (the grooves 17c1A and 17c1B) is the groove 17c1A or the groove 17c1B, the width x1 of the groove 17c1 preferably satisfies t1<x1<x2, as described above. In addition, regardless of whether the groove 17c1 is the groove 17c1A or the groove 17c1B, when the bottom portion 17c2 of the groove 17c1 includes a flat portion, the groove 17c1 preferably satisfies 0<x3<t1.

Furthermore, when the depth of the groove 17c1A of the shallow groove portion D1 is t2A, and the depth of the groove 17c1B of the deep groove portion D2 is t2B, t2A<t2B is preferably satisfied, and the depths t2A and t2B of these grooves 17c1A and 17c1B (namely, the depth t2 of the groove 17c1) are preferably within the range of 0.5 μm to 2 μm, for example, as described above.

### Fourth Modified Example

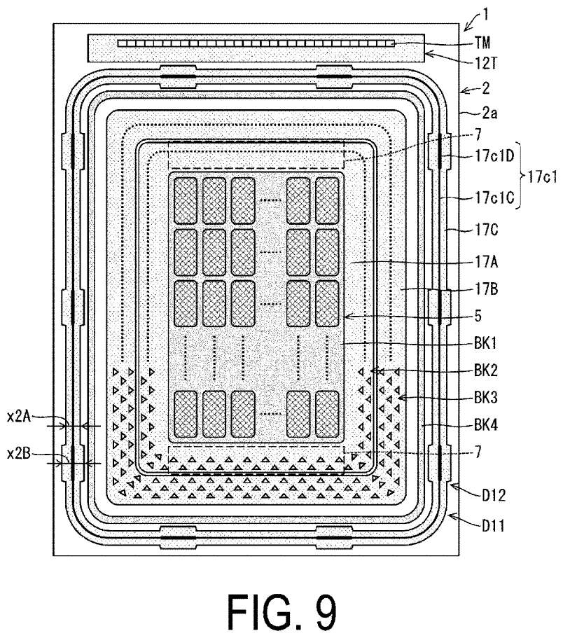

FIG. 9 is a plan view illustrating an example of a schematic configuration of the organic EL display device 1 according to the present modified example.

As illustrated in FIG. 9, in the organic EL display device 1 according to the present modified example, the width of the third organic insulating film pattern portion 17C in a plan view may be partially different, and in a plan view, as a groove 17c1, a groove 17c1C and a groove 17c1D, which has a groove width wider than that of the groove 17c1C, may be periodically provided.

For example, the groove 17c1C having the relatively narrow groove width may be provided, as a narrow groove, in a narrow width portion D11 in which the width of the third organic insulating film pattern portion 17C is relatively narrow, and the groove 17c1D having the relatively wide groove width may be provided, as a wide groove, in a wide width portion D12 in which the width of the third organic insulating film pattern portion 17C is relatively wide. Note that in FIG. 9, a case is illustrated, as an example, in which the narrow width portion D11 and the wide width portion D12 are alternately provided at a uniform period, but the present modified example is not limited to this example.

Furthermore, the grooves 17c1C and 17c1D having different depths may be provided respectively in the narrow width portion D11 and the wide width portion D12, and the grooves 17c1C and 17c1D having different shapes may be provided respectively in the narrow width portion D11 and the wide width portion D12.

In addition, in FIG. 9, an example is illustrated in which the narrow width sections D11 are provided in the corner portions of the organic EL substrate 2, but the wide width portions D12 may be provided in the corner portions of the organic EL substrate 2. For example, in FIG. 9, the narrow width portions D11 and the wide width portions D12 may be reversed in position.

Furthermore, in FIG. 9, a case is illustrated, as an example, in which the third organic insulating film pattern portion 17C provided with the narrow width portions D11 and the wide width portions D12 is formed in a single frame shape, but the present modified example is not limited to this example. For example, the third organic insulating film pattern portion 17C provided with the narrow width portions D11 and the wide width portions D12 may be formed in a multiple frame shape, such as a double-frame shape, a triple frame shape, or the like, and the narrow width portions D11 and the wide width portions D12 may be disposed to respectively form zig-zag patterns in adjacent frames.

As illustrated in FIG. 9, when the width x2, in the same direction as the width x1, at the outermost surface of the third organic insulating film pattern portion 17C in the narrow width portion 11 is x2A, and the width x2, in the same direction as the width x1, at the outermost surface of the third organic insulating film pattern portion 17C in the wide width portion D12 is x2B, x2A<x2B is satisfied.

The width x2A is preferably within a range of 7 μm to 15 μm, for example, for the reason of frame narrowing. The width x2B is preferably within a range of 9 μm to 25 μm, for example, for the reason of frame narrowing.

Furthermore, regardless of whether the groove 17c1 (the grooves 17c1C and 17c1D) is the groove 17c1C or the groove 17c1D, the width x1 of the groove 17c1 preferably satisfies t1<x1 <x2, as described above. In addition, regardless of whether the groove 17c1 is the groove 17c1C or the groove 17c1D, when the bottom portion 17c2 of the groove 17c1 includes a flat portion, the groove 17c1 preferably satisfies 0<x3 <t1. The width x2 can be replaced as appropriate with the width x2A or the width x2B depending on whether the groove 17c1 is a groove provided in the narrow width portion D11 or a groove provided in the wide width portion D12. Note that the widths x1 and x3, the layer thickness t1, and the depth t2 are set as described above.

Furthermore, in the present embodiment as well, the taper angle θ of the groove 17c1 (the grooves 17c1C and 17c1D) is preferably within the range of 70° to 120°, for example, as described above.

### Fifth Modified Example

Furthermore, in FIG. 1, a case is illustrated, as an example, in which the organic insulating film 17 includes the first organic insulating film pattern portion 17A to the fourth organic insulating film pattern portion 17D. However, the present embodiment is not limited to this example.

For example, the third organic insulating film pattern portion 17C and the fourth organic insulating film pattern portion 17D need not necessarily be provided separately, and the third organic insulating film pattern portion 17C may cover the terminal portion 12T to expose the terminals TM.

### Sixth Modified Example

Furthermore, in FIG. 2, a case is illustrated, as an example, in which the third organic insulating film pattern portion 17C in which the groove 17c1 is formed is formed in the frame shape to surround the bank BK4. However, the present embodiment is not limited to this example.

For example, when the first inorganic layer 31 and the second inorganic layer 33 are formed in regions other than the terminals TM using a CVD mask such that the first inorganic layer 31 and the second inorganic layer 33 are not formed on the terminals TM, the groove 17c1 or the third organic insulating film pattern portion 17C in which the groove 17c1 is formed need not necessarily be formed between the display region 5 and the terminal portion 12T.

### Seventh Modified Example

In the present embodiment, a case is described, as an example, in which the sealing film 30 includes the first inorganic layer 31 and the second inorganic layer 33, and the first inorganic layer 31 and the second inorganic layer 33 are layered on the edge portion 2a of the organic EL substrate 2 (in other words, on the division line DL) and on the top surface of the third organic insulating film pattern portion 17C.

However, the present embodiment is not limited to this example, and may have a configuration in which only one of the inorganic layers of the first inorganic layer 31 and the second inorganic layer 33 is formed on the edge portion 2a of the organic EL substrate 2 and on the top surface of the third organic insulating film pattern portion 17C.

### Eighth Modified Example

An object of the disclosure is to prevent the crack generated in the sealing film 30 from spreading into the display region 5, as described above, and in FIG. 1, a case is illustrated, as an example, in which the inorganic films, such as the gate insulating film 14 and the inorganic insulating film 15 (the passivation film) that are formed in the TFT step are formed on the edge portion 2a of the organic EL substrate 2 (in other words, on the division line DL). Since these inorganic films are typically formed by plasma CVD using a higher temperature than that for the inorganic sealing film, these inorganic films have strong crack resistance properties.

However, the present embodiment is not limited to this example. To prevent cracks from occurring in these inorganic films formed at the TFT step, these inorganic films on the division line DL may be removed by photolithography, etching, or the like at a step for forming the inorganic films.

### Ninth Modified Example

As described above, in the present embodiment, as an example of the display device according to the present embodiment, the organic EL display device 1 including the organic EL elements 24 (the OLED elements) as the light emitting elements is described as an example. However, the present embodiment is not limited to this example, and the light emitting elements may be inorganic EL elements or Quantum-dot Light Emitting Diode (QLED) elements.

### Supplement

A display device (the organic EL display device 1) according to a first aspect of the disclosure includes a support body (the TFT substrate 10), a plurality of light emitting elements (the organic EL elements 24) provided in the display region 5 on the support body, and the sealing film 30 configured to seal the plurality of light emitting elements. The display device includes a resin layer (the third organic insulating film pattern portion 17C) including a groove (the groove 17c1) on an upper surface thereof, the resin layer being provided between the display region 5 and at least part of an edge portion of the support body (the edge portion 2a of the organic EL substrate 2 provided with the TFT substrate 10) in a plan view, and being separated from the at least part of the edge portion. The sealing film 30 includes at least an inorganic layer (the first inorganic layer 31 and the second inorganic layer 33), and, in a plan view, the inorganic layer covers the resin layer and the at least part of the edge portion, and is split apart in the groove.

According to a second aspect of the disclosure, in the display device according to the first aspect, the resin layer may be provided facing the at least part of the edge portion on which the inorganic layer is provided.

According to a third aspect of the disclosure, in the display device according to the first or second aspect, the display region 5 may include the plurality of subpixels 3, the plurality of light emitting elements may each include the first electrode 21, a function layer (the organic EL layer 22) including a light emitting layer, and the second electrode 23, the first electrode 21, the function layer, and the second electrode 23 being layered in this order. At least the first electrode 21 may be provided for each of the plurality of subpixels 3. The second electrode connecting portion 7 electrically connected to the second electrode 23 may be provided outside the display region 5. The resin layer may be provided outside the second electrode connecting portion 7.

According to an fourth aspect of the disclosure, in the display device according to any one of the first to third aspects, the sealing film 30 may include the first inorganic layer 31, the second inorganic layer 33, and the organic layer 32 sealed between the first inorganic layer 31 and the second inorganic layer 33 and covering the display region 5, and the resin layer may be provided outside an edge portion of the organic layer 32 (namely, outside the sealing region 8).

According to a fifth aspect of the disclosure, in the display device according to any one of the first to fourth aspects, the support body may have a quadrilateral shape in a plan view, the terminal portion 12T may be provided between at least one side of four sides of the support body and the display region 5, along the at least one side, and the resin layer may be provided facing at least an edge portion, of the support body, of a side on which the terminal portion 12T is not provided.

According to a sixth aspect of the disclosure, in the display device according to the fifth aspect, the resin layer may be further provided between the display region 5 and the terminal portion 12T.

According to a seventh aspect of the disclosure, in the display device according to any one of the first to sixth aspects, in a plan view, the resin layer may be formed in a frame shape surrounding the display region 5.

According to an eighth aspect of the disclosure, in the display device according to any one of the first to seventh aspects, in a plan view, a peripheral edge portion of the inorganic layer overlaps with a peripheral edge portion (the whole edge portion 2a) of the support body.

According to a ninth aspect of the disclosure, in the display device according to any one of the first to eighth aspects, the resin layer may include the shallow groove portion D1 having a relatively shallow depth of the groove, and the deep groove portion D2 having a relatively deep depth of the groove.

According to a tenth aspect of the disclosure, in the display device according to the ninth aspect, the deep groove portions D1 may be periodically provided.

According to an eleventh aspect of the disclosure, in the display device according to the ninth or tenth aspect, the groove in the shallow groove portion D1 and the groove in the deep groove portion D2 may have different shapes.

According to a twelfth aspect of the disclosure, in the display device according to any one of the first to eleventh aspects, the resin layer may include a narrow width portion having a width of the resin layer being relatively narrow and a wide width portion having the width of the resin layer being relatively wide.

According to a twelfth aspect of the disclosure, in the display device according to the twelfth aspect, a narrow groove having the width being relatively narrow may be provided as the groove in the narrow width portion D11, and a wide groove having the width being relatively wide may be provided as the groove in the wide width portion D12.

According to a fourteenth aspect of the disclosure, in the display device according to any one of the first to eleventh aspects, the resin layer may include the narrow width portion D11 having a width of the groove being relatively narrow, and the wide width portion D12 having the width of the groove being relatively wide.

According to a fifteenth aspect of the disclosure, in the display device according to any one of the twelfth to fourteenth aspects, the wide width portions D12 may be periodically provided.

According to a sixteenth aspect of the disclosure, in the display device according to any one of the first to fifteenth aspects, the plurality of light emitting elements may each be provided on a flattening film (the first organic insulating film pattern portion 17A) provided in the display region 5, and the resin layer may be formed of the same material as the flattening film and provided in the same layer as the flattening film being while being separated from the flattening film.

According to a seventeenth aspect of the disclosure, in the display device according to any one of the first to sixteenth aspects, the resin layer may further include a frame-shaped wall body (the bank BK5) surrounding the display region 5, and the groove may be provided surrounding the frame-shaped wall body.

According to an eighteenth aspect of the disclosure, in the display device according to any one of the first to seventeenth aspects, an angle formed by an inner wall of the groove and a plane parallel to a surface of the support body may be within a range of 70° to 120°.

According to a nineteenth aspect of the disclosure, in the display device according to any one of the first to eighteenth aspects, a depth of the groove may be within a range of 0.5 μm to 2 μm.

According to a twentieth aspect of the disclosure, in the display device according to any one of the first to nineteenth aspects, when a width of an upper end of the groove in a direction orthogonal to a direction along an edge portion of the support body in a plan view is x1, a width, in the same direction as the width of the upper end of the groove, at an outermost surface of the resin layer is x2, and a layer thickness of the inorganic layer on the resin layer is t1, t1<x1<x2 may be satisfied.

According to a twenty first aspect of the disclosure, in the display device according to any one of the first to twentieth aspects, the groove may include a flat portion in a bottom portion (the bottom portion 17c2) thereof, and when a width of the flat portion in the bottom portion of the groove in a direction orthogonal to a direction along the edge portion of the support body in a plan view is x3 and the layer thickness of the inorganic layer on the resin layer is t1, 0<x3<t1 may be satisfied.

According to a twenty second aspect of the disclosure, in the display device according to any one of the first to twenty first aspects, the width of the groove may be within a range of 2 μm to 5 μm.

According to a twenty third aspect of the disclosure, in the display device according to any one of the first to twenty second aspects, the display device may be a flexible display device.

In a method for manufacturing the display device according to a twenty fourth aspect of the disclosure, the display device (the organic EL display device 1) includes a support body (the TFT substrate 10), a plurality of light emitting elements (the organic EL elements 24) provided in a display region 5 on the support body, and the sealing film 30 configured to seal the plurality of light emitting elements. The method includes forming a resin layer (the third organic insulating film pattern portion 17C) including a groove (the groove 17c1) in an upper surface thereof on the mother substrate 50 configuring at least part of the support body, the resin layer being formed, in a plan view, between at least part of a scheduled division line (the division line DL), of a plurality of the scheduled division lines for dividing and singulating the mother substrate 50 into the individual display devices, and the display region 5 in a region surrounded by the plurality of scheduled division lines, the resin layer being separated from the at least part of the plurality of scheduled division lines, forming the sealing film 30, and dividing the mother substrate 50, on which the sealing film 30 is formed, along the plurality of scheduled division lines surrounding around each of the display regions 5. The forming the sealing film includes forming an inorganic layer (the first inorganic layer 31 and the second inorganic layer 33), and in the forming the inorganic layer, the inorganic layer covers the resin layer, and by forming the inorganic layer to also cover the at least part of the plurality of scheduled division lines, the inorganic layer is split apart in the groove.

According to a twenty fifth aspect of the disclosure, in the method for manufacturing the display device according to the twenty fourth aspect, in the forming the resin layer, the resin layer may be formed facing the at least part of the plurality of scheduled division lines.

According to a twenty sixth aspect of the disclosure, in the method for manufacturing the display device according to the twenty fourth or twenty fifth aspect, in the forming the resin layer, the resin layer may be formed, in a plan view, in a frame shape surrounding the display region 5, inside the region surrounded by the plurality of scheduled division lines.

According to a twenty seventh aspect of the disclosure, in the method for manufacturing the display device according to the twenty fourth or twenty fifth aspect, the dividing the mother substrate 50 may further include dividing the mother substrate 50 into quadrilateral shapes in a plan view along the plurality of scheduled division lines, and forming the terminal portion 12T along part of the plurality of scheduled division lines, of the plurality of scheduled division lines corresponding to four sides of a region of the quadrilateral shape, between the part of the plurality of scheduled division lines and the display region 5 in the region having the quadrilateral shape surrounded by the plurality of scheduled division lines. In the forming the resin layer, the resin layer may be formed facing at least the scheduled division line on the side on which the terminal portion 12T is not provided, of the four sides of the region of the quadrilateral shape.

According to a twenty eighth aspect of the disclosure, the method for manufacturing the display device according to the twenty seventh aspect may further include covering, with a resin, the terminal portion 12T formed in the forming the terminal portion. In the forming the resin layer, the resin layer may be formed in a frame shape surrounding the display region 5 and passing between the display region 5 in the region of the quadrilateral shape and the terminal portion 12T, and in the forming the inorganic layer, the inorganic layer may be formed in a maskless manner over a whole surface of the mother substrate 50 such that the resin layer and each of the plurality of scheduled division lines are covered by the inorganic layer. After the forming the inorganic layer, the method may further include exposing the terminal TM of the terminal portion 12T.

According to a twenty ninth aspect of the disclosure, in the method for manufacturing the display device according to the twenty eighth aspect, the exposing the terminal is performed by irradiating the terminal portion 12T with a laser.

The disclosure is not limited to each of the embodiments described above, and various modifications may be made within the scope of the claims. Embodiments obtained by appropriately combining technical approaches disclosed in each of the different embodiments also fall within the technical scope of the disclosure. Moreover, novel technical features can be formed by combining the technical approaches disclosed in the embodiments.

### REFERENCE SIGNS LIST

1 Organic EL display device

2 Organic EL substrate

2a Edge portion

3, 3R, 3G, 3B Subpixel

4 Pixel

5 Display region

6 Frame region

7 Second electrode connecting portion

8 Sealing region

10 TFT substrate (support body)

12T Terminal portion

14 Gate insulating film

15, 16 Inorganic insulating film

17 Organic insulating film

17A First organic insulating film pattern portion (flattening film)

17B Second organic insulating film pattern portion

17C Third organic insulating film pattern portion (resin layer)

17D Fourth organic insulating film pattern portion

17c1, 17c1A, 17c1B, 17c1C, 17c1D Groove

17c2 Bottom portion

18 First resin layer

19 Second resin layer

21 First electrode

22 Organic EL layer (function layer)

23 Second electrode

24 Organic EL element (light emitting element)

30 Sealing film

31 First inorganic layer

32 Organic layer

33 Second inorganic layer

34 Split portion

50 Mother substrate

BK, BK1, BK2, BK3, BK4, BK5 Bank

DL Division line (scheduled division line)

D1 Shallow groove portion

D2 Deep groove portion

D11 Narrow width portion

D12 Wide width portion

1. A display device comprising:
a support body;
a plurality of light emitting elements provided in a display region on the support body; and
a sealing film configured to seal the plurality of light emitting elements,
wherein the display device further includes a resin layer including a groove on an upper surface thereof, the resin layer being provided between the display region and at least part of an edge portion of the support body in a plan view, and being separated from the at least part of the edge portion,
the sealing film includes at least an inorganic layer, and
in a plan view, the inorganic layer covers the resin layer and the at least part of the edge portion, and is split apart in the groove.

2. The display device according to claim 1,
wherein the resin layer is provided facing the at least part of the edge portion on which the inorganic layer is provided.

3. The display device according to claim 1 or 2,
wherein the display region includes a plurality of subpixels,
the plurality of light emitting elements each includes a first electrode, a function layer including a light emitting layer, and a second electrode, the first electrode, the function layer, and the second electrode being layered in this order,
at least the first electrode is provided for each of the plurality of subpixels,
a second electrode connecting portion electrically connected to the second electrode is provided outside the display region, and
the resin layer is provided outside the second electrode connecting portion.

4. The display device according to claim 1,
wherein the sealing film includes a first inorganic layer, a second inorganic layer, and an organic layer sealed between the first inorganic layer and the second inorganic layer and covering the display region, and
the resin layer is provided outside an edge portion of the organic layer.

5. The display device according to claim 1,
wherein the support body has a quadrilateral shape in a plan view,
a terminal portion is provided between at least one side of four sides of the support body and the display region, along the at least one side, and
the resin layer is provided facing at least an edge portion, of the support body, of a side on which the terminal portion is not provided.

6. The display device according to claim 5,
wherein the resin layer is further provided between the display region and the terminal portion.

7. The display device according to claim 1,
wherein, in a plan view, the resin layer is formed in a frame shape surrounding the display region.

8. The display device according to claim 1,
wherein, in a plan view, a peripheral edge portion of the inorganic layer overlaps with a peripheral edge portion of the support body.

9. The display device according to claim 1,
wherein the resin layer includes a shallow groove portion having a relatively shallow depth of the groove, and a deep groove portion having a relatively deep depth of the groove.

10. The display device according to claim 9,
wherein the deep groove portions are periodically provided.

11. The display device according to claim 9,
wherein the groove in the shallow groove portion and the groove in the deep groove portion have different shapes.

12. The display device according to claim 1,
wherein the resin layer includes a narrow width portion having a width of the resin layer being relatively narrow and a wide width portion having the width of the resin layer being relatively wide.

13. The display device according to claim 12,
wherein a narrow groove having the width being relatively narrow is provided as the groove in the narrow width portion, and a wide groove having the width being relatively wide is provided as the groove in the wide width portion.

14. The display device according to claim 1,
wherein the resin layer includes the narrow width portion having a width of the groove being relatively narrow, and the wide width portion having the width of the groove being relatively wide.

15. The display device according to claim 12,
wherein the wide width portions are periodically provided.

16. The display device according to claim 1,
wherein the plurality of light emitting elements is each provided on a flattening film provided in the display region, and
the resin layer is formed of the same material as the flattening film and provided in the same layer as the flattening film while being separated from the flattening film.

17. The display device according to claim 1,
wherein the resin layer further includes a frame-shaped wall body surrounding the display region, and
the groove is provided surrounding the frame-shaped wall body.

18. The display device according to claim 1,
wherein an angle formed by an inner wall of the groove and a plane parallel to a surface of the support body is within a range of 70° to 120°.

19. (canceled).

20. The display device according to claim 1,
wherein when a width of an upper end of the groove in a direction orthogonal to a direction along an edge portion of the support body in a plan view is x1, a width, in the same direction as the width of the upper end of the groove, at an outermost surface of the resin layer is x2, and a layer thickness of the inorganic layer on the resin layer is t1, t1<x1<x2 is satisfied.

21. The display device according to claim 1,
wherein the groove includes a flat portion in a bottom portion thereof, and
when a width of the flat portion in the bottom portion of the groove in a direction orthogonal to a direction along the edge portion of the support body in a plan view is x3 and the layer thickness of the inorganic layer on the resin layer is t1, 0<x3<t1 is satisfied.

22-29. (canceled)
